(19) United States
(12) Patent Application Publication
(10) Pub. No.: US 2024/0399867 A1
(43) Pub. Date: Dec. 5, 2024

(54) COLD-FORMED OLED DISPLAYS WITH SPLIT NEUTRAL PLANES AND METHODS FOR FABRICATING THE SAME

(71) Applicant: CORNING INCORPORATED, CORNING, NY (US)

(72) Inventors: Khaled Layouni, Fontainebleau (FR); Yousef Kayed Qaroush, Painted Post, NY (US); Tingge Xu, San Jose, CA (US)

(21) Appl. No.: 18/700,580

(22) PCT Filed: Oct. 3, 2022
(86) PCT No.: PCT/US2022/045504

§ 371 Date: Apr. 11, 2024

Related U.S. Application Data
(60) Provisional application No. 63/271,855, filed on Oct. 26, 2021.

(51) Int. Cl. B60K 35/22; B60K 37/20; H10K 59/80; H10K 77/10; H10K 102/00

(52) U.S. Cl. CPC B60K 35/223; H10K 59/8722; H10K 77/111; B60K 37/20; B60K 2360/84; H10K 2102/311; H10K 2102/351

(57) ABSTRACT

Disclosed is display device for a vehicle interior system including a glass substrate comprising a length extending in a first direction that is greater than or equal to 200 mm. An organic light emitting diode (OLED) display module is disposed on a major surface of the glass substrate, the OLED display module comprising a plurality of functional layers. A support structure is mechanically coupled to the glass substrate and the OLED display module to retain the glass substrate and the OLED display module in a curved configuration. A plurality of adhesive layers attach the OLED display module to the second major surface and a plurality of functional layers of the OLED display module to one another. Each adhesive layer comprises a Young's modulus that is less than or equal 1.5 MPa to decouple strain distributions in the glass substrate and the plurality of functional layers from one another.

### PRIORITY

This application claims the benefit of priority under 35 U.S.C. § 120 of U.S. Application No. 63/271,855 filed on Oct. 26, 2021, the content of which is relied upon and incorporated hereby by reference in its entirety.

### FIELD

The disclosure relates to display devices for vehicle interior systems and, more particularly, to organic light emitting diode (OLED) display devices for vehicle interior systems that may be cold-formed in conjunction with a glass substrate to include a desired three-dimensional shape.

### BACKGROUND

Vehicle interiors include curved surfaces and can incorporate displays in such curved surfaces. Curved glass substrates are desirable as covers for such displays due to their optical performance and durability. Various techniques are used to fabricate such curved glass substrates, including cold-forming, where a glass substrate is shaped at a relatively low temperature after the glass substrate is fabricated. Such cold-forming techniques advantageously permit glass substrates to remain in a flat (e.g., planar) shape during various fabrication steps (e.g., during post-processing, decoration and transport), thereby reducing production costs. Even greater cost savings may be realized if display panels (e.g., OLED display panels) are also shaped through cold-forming, as display panels that are initially flat can be shaped to possess a desired curvature, permitting flexible designs. Cold-forming display panels, however, may place functional display components under strain, leading to some risk of display failure over the course of the display's lifetime. Such risks may be particularly acute for relatively large display panels including lengths of 100 mm or more along a direction of curvature, as bending displays of such length may tend to result in greater strain accumulation. As a result, there are concerns associated with the reliability of cold-formed display panels, especially over relatively long use lifetimes (e.g., more than 5 years) associated with typical automotive applications.

### SUMMARY

According to an embodiment of the present disclosure, a display device for a vehicle interior system includes a glass substrate comprising a first major surface and second major surface opposite the first major surface, wherein the glass substrate comprises a length extending in a first direction that is greater than or equal to 200 mm. The display device also includes an organic light emitting diode (OLED) display module disposed on the second major surface, the OLED display module comprising a plurality of functional layers. The display device also includes a support structure mechanically coupled to the glass substrate and the OLED display module to retain the glass substrate and the OLED display module in a curved configuration. The display device also includes a plurality of adhesive layers comprising an attachment adhesive layer attaching the OLED display module to the second major surface and a plurality of layers of display adhesive attaching the plurality of functional layers to one another. The plurality of adhesive layers may include n adhesive layers. Each of the plurality of adhesive layers comprises a Young's modulus that is less than or equal 1.5 MPa to decouple strain distributions in the glass substrate and the plurality of functional layers from one another.

According to another embodiment, a vehicle interior system includes a glass substrate comprising a first major surface and a second major surface opposite the first major surface, wherein the glass substrate comprises a length extending in a first direction that is greater than or equal to 200 mm and a width extending in a second direction perpendicular to the first direction that is greater than or equal to 100 mm. The vehicle interior system also includes a support structure mechanically coupled to the glass substrate and retaining the glass substrate in a curved configuration such that at least a portion of the glass substrate is curved along at least one of the first direction and the second direction. The vehicle interior system also includes an organic light emitting diode (OLED) display module attached to the second major surface via an attachment adhesive layer disposed directly on the second major surface. The OLED display module is retained in the curved configuration via the attachment adhesive layer such that different portions of the OLED display module are placed in tension and compression. The OLED display module comprises a plurality of functional layers attached to one another via a plurality of layers of display adhesive disposed between successive ones of the plurality of functional layers. The plurality of layers of display adhesive each comprise a Young's modulus and thickness selected such that the compression and tension placed on the different portions of the OLED display module results in each of the plurality of functional layers and each of the plurality of layers of display adhesive containing a separate neutral plane.

According to another embodiment of the present disclosure, a method of manufacturing a display device includes attaching an organic light emitting diode (OLED) display module to a glass substrate via an attachment adhesive layer, wherein the glass substrate comprises a first major surface and a second major surface opposing the first major surface and a length in a first direction that is greater than or equal to 200 mm, wherein the OLED display module comprises a plurality of functional layers attached to one another via a plurality of layers of display adhesive and wherein the OLED display module comprises a planar shape prior to being attached to the glass substrate. The method also includes bending the OLED display module into a curved configuration that corresponds to the glass substrate, wherein the bending of the OLED display module results in each of the plurality of functional layers and the plurality of layers of display adhesive comprising a separate neutral plane representing a surface of zero bending strain.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification.

### BRIEF DESCRIPTION OF THE DRAWINGS

The accompanying drawings incorporated in and forming a part of the specification illustrate several aspects of the present invention and, together with the description, serve to explain the principles of the invention. In the drawings:

FIG. 1 is a perspective view of a vehicle interior with vehicle interior systems having OLED displays, according to one or more embodiments of the present disclosure;

FIG. 2 schematically depicts a cross-sectional view of an OLED display of a vehicle interior system through the line II-II depicted in FIG. 1, according to one or more embodiments of the present disclosure;

FIG. 3 schematically depicts a cross-sectional view of the OLED display through the line III-III depicted in FIG. 2, according to one or more embodiments of the present disclosure;

FIG. 4 depicts a flow diagram of a method of attaching an OLED display module to a glass substrate and cold-forming the OLED display module into a curved configuration, according to one or more embodiments of the present disclosure;

FIG. 5A schematically depicts a cross-sectional view of a first step of a process of cold-forming a glass substrate and an OLED display module, according to one or more embodiments of the present disclosure;

FIG. 5B schematically depicts a cross-sectional view of a second step of the process of cold-forming the glass substrate and the OLED display module depicted in FIG. 5A, where the OLED display module and the glass substrate are placed into a curved configuration to form a plurality of neutral planes, according to one or more embodiments of the present disclosure;

FIG. 6A schematically depicts a cross-sectional view of a pre-cold-formed glass substrate that may be a component of an OLED display of a vehicle interior system, according to one or more embodiments of the present disclosure;

FIG. 6B schematically depicts a step in a process of cold-forming an OLED display module against the pre-cold-formed glass substrate depicted in FIG. 6A to form a plurality of neutral planes, according to one or more embodiments of the present disclosure;

FIG. 7 schematically depicts a perspective view of a glass substrate, according to one or more embodiments of the present disclosure;

FIG. 8 depicts a plot of results of a finite element analysis simulation of a multi-layer display stack, including three bending strain distributions for different layers of attachment adhesive having different Young's moduli, according to one or more embodiments of the present disclosure;

FIG. 9 depicts a plot of results of a finite element analysis simulation of a multi-layer display stack, including a first bending strain distribution associated with an attachment adhesive layer having a first thickness and a second bending strain distribution associated with an attachment adhesive layer having a second thickness, according to one or more embodiments of the present disclosure;

FIG. 10A, depicts a plot of results of a finite element analysis simulation of a multi-layer display stack with an attachment adhesive layer having a first Young's modulus, including a first bending strain distribution for the display stack having a first length and a second bending strain distribution for the display stack having a second length, according to one or more embodiments of the present disclosure;

FIG. 10B, depicts a plot of results of a finite element analysis simulation of a multi-layer display stack with an attachment adhesive layer having a second Young's modulus, including a first bending strain distribution for the display stack having a first length and a second bending strain distribution for the display stack having a second length, according to one or more embodiments of the present disclosure; and

FIG. 10C, depicts a plot of results of a finite element analysis simulation of a multi-layer display stack with an attachment adhesive layer having a third Young's modulus, including a first bending strain distribution for the display stack having a first length and a second bending strain distribution for the display stack having a second length, according to one or more embodiments of the present disclosure.

### DETAILED DESCRIPTION

Referring generally to the figures, described herein are embodiments of vehicle interior systems including cold-formed organic light emitting diode (OLED) display modules and methods of fabricating the same. The vehicle interior systems described herein may include a curved glass substrate and an OLED display module disposed on a major surface of the curved glass substrate. The OLED display module may include a plurality of functional layers, with each of the functional layers including one or more functional components (e.g, display layer, polarization layer, touch sensitive layer). A plurality of adhesive layers attach the OLED display module to the curved glass substrate and the plurality of functional layers to one another. The curved glass substrate and the OLED display module may be cold-formed into a curved configuration and retained in the curved configuration by a support structure, which may result in bending strain being placed on the curved glass substrate and the plurality of functional layers. Various aspects (e.g., Young's modulus, thickness) of the plurality of adhesive layers are selected to split neutral planes associated with the bending strain. For example, in embodiments, the plurality of adhesive layers are selected based on one or more of a dimension of the OLED display module along a direction of curvature of the OLED display module, thicknesses of the curved glass substrate and the plurality of functional layers, and material properties (e.g., Young's modulus, Poisson's ratio) of the curved glass substrate and the plurality of functional layers to effectively split the natural planes. Splitting the neutral planes beneficially decouples bending strain distributions of various portions of the system from one another, thereby reducing overall residual strains in the system and reducing the probability of component failure.

In embodiments, the plurality of adhesive layers includes n adhesive layers, and aspects of each of the plurality of adhesive layers (e.g., in terms of the composition of adhesives used in each of adhesive layer and thickness of each adhesive layer) are selected such that the vehicle interior system comprises m=2n+1 neutral planes of zero bending strain as a result of the cold-forming of the curved glass substrate and/or the OLED display module. For each adhesive layer in the plurality of adhesive layers, there may be one neutral plane located in the adhesive layer, as well as two neutral planes located in two components (e.g., the curved glass substrate, one of the plurality of functional layers of the OLED display module) disposed adjacent to the adhesive layer. Such a number of neutral planes beneficially aids in reducing the maximum bending strain in each layer of the vehicle interior system by decoupling the bending strain distributions in each layer. As a result, the vehicle interior systems described herein may facilitate cold bending of OLED display modules with improved reliability.

Throughout the disclosure, a Young's modulus and/or a Poisson's ratio is measured for polymer-based and adhesive materials using the dynamic mechanical analysis techniques described in ASTM D4065. These properties may also be measured via tensile testing, such as the tests described in ASTM D638 (for glassy polymers such as PET) and ASTM D412 (for elastomeric materials and adhesives, such as optically-clear adhesives). A flexural rigidity of a material is the product of the Young's modulus of the material and a cube of the thickness of the material divided by 12 times the quantity of 1 minus a square of the Poisson's ratio of the material.

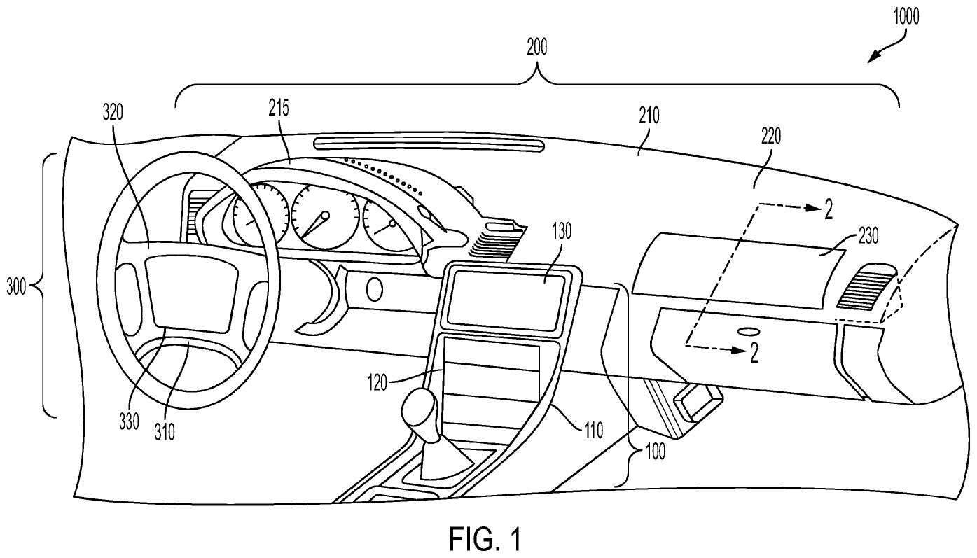

FIG. 1 shows an exemplary vehicle interior 1000 that includes three different embodiments of a vehicle interior system 100, 200, 300. Vehicle interior system 100 includes a frame, shown as center console base 110, with a curved surface 120 including an OLED display 130. Vehicle interior system 200 includes a frame, shown as dashboard base 210, with a curved surface 220 including an OLED display 230. The dashboard base 210 typically includes an instrument panel 215 which may also include an OLED display. Vehicle interior system 300 includes a frame, shown as steering wheelbase 310, with a curved surface 320 and an OLED display 330. It should be understood that vehicle interior systems other than the vehicle interior systems 100, 200, 300 depicted in FIG. 1 may incorporate OLED displays as described herein. OLED displays other than the OLED displays 130, 230, 330 are contemplated and within the scope of the present disclosure. For example, in embodiments, a vehicle interior system may include a frame for attachment of an OLED display module, and the frame may be incorporated into any portion of an interior of a vehicle that includes a curved surface, such as, but not limited to, an arm rest, a pillar, a roof, a seat back, a floor board, a headrest, a door panel, or any portion of the interior of a vehicle that includes a curved surface. In embodiments, the OLED displays described herein may be incorporated into a free-standing display (i.e., a display that is not permanently connected to a portion of the vehicle).

The OLED displays of the present disclosure may have a variety of sizes and shapes. Additionally, the OLED displays 130, 230, 330 depicted in FIG. 1 as being separate from one another may also be integrated into a single OLED display. For example, in embodiments, the OLED displays 130, 230, 330 may be integrated into a single OLED display that extends over the dashboard base 210 from the instrument panel 215 to the location of the OLED display 230 depicted in FIG. 1. In embodiments, the OLED display devices described herein may include glass substrates that also cover non-display surfaces for the dashboard, center console, door panel, etc. In such embodiments, glass material may be selected based on its weight, aesthetic appearance, etc. and may be provided with a coating (e.g., an ink or pigment coating) with a pattern (e.g., a brushed metal appearance, a wood grain appearance, a leather appearance, a colored appearance, etc.) to visually match the glass components with adjacent non-glass components. In embodiments, such ink or pigment coating may have a transparency level that provides for deadfront or color matching functionality when the OLED display is inactive.

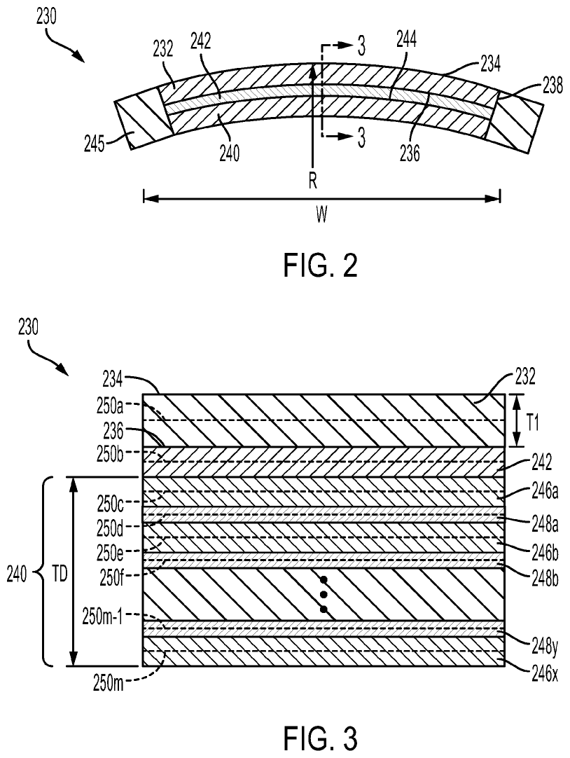

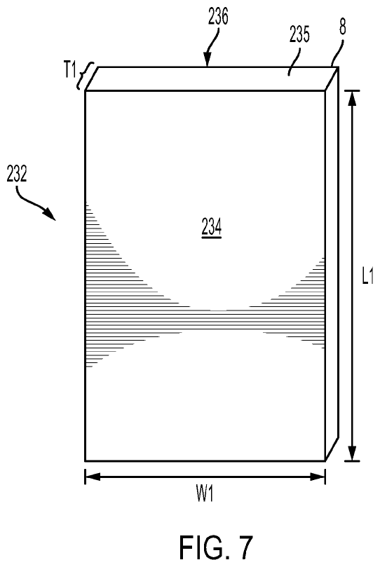

In embodiments, each of the OLED displays 130, 230, 330 includes a glass substrate and an OLED display module disposed on the glass substrate. For example, FIG. 2 depicts a cross sectional view of the OLED display 230 through the line II-II of FIG. 1, according to an example embodiment. The OLED display 230 is depicted to include a glass substrate 232 including a first major surface 234, a second major surface 236, and a minor surface 238 extending between the first major surface 234 and the second major surface 236. An OLED display module 240 is disposed on the second major surface 236 and attached to the second major surface 236 via an attachment adhesive layer 242. The OLED display module 240 includes a front surface 244 that is covered by the glass substrate 232 such that the glass substrate 232 functions as a cover lens for the OLED display module 240. In embodiments, a dimension W represents a dimension of the glass substrate 232 prior to cold-forming (e.g, representing a length or width of the glass substrate 232 prior to cold-forming), corresponding to the width W1 described herein (see FIG. 7). In embodiments, the dimension W is greater than or equal to 100 mm (e.g., greater than or equal to 200 mm, greater than or equal to 300 mm, greater than or equal to 400 mm, greater than or equal to 500 mm, greater than or equal to 1000 mm, greater than or equal to 1500 mm, and any and all ranges between and including the aforementioned ranges).

Referring to FIGS. 1-2, in embodiments, components of the OLED displays 130, 230, and 330 are curved to match or substantially match a curvature of one of the curved surfaces 120, 220, 320. As shown in FIG. 2, for example, the glass substrate 232 is curved such that at least a portion of the first major surface 234 includes a radius of curvature R. The radius of curvature R may correspond to a radius of curvature of the curved surface 220 (see FIG. 1) of the vehicle interior system 200.

In embodiments, the radius of curvature R is a minimum radius of curvature of the first major surface 234 along the depicted direction of curvature. In embodiments, R greater than or equal to 50 mm (e.g., greater than or equal to 60 mm, greater than or equal to 70 mm, greater than or equal to 80 mm, greater than or equal to 90 mm, greater than or equal to 100 mm, greater than or equal to 110 mm, greater than or equal to 120 mm, greater than or equal to 130 mm, greater than or equal to 140 mm, greater than or equal to 150 mm). In embodiments, the radius of curvature R varies depending on a thickness (T1—see FIG. 7) of the glass substrate 232. In embodiments where glass substrate 232 has a relatively large thickness (e.g., greater than or equal to 1.0 mm, for example), the radius of curvature R may be greater than or equal to 150 mm (e.g., greater than or equal to 200 mm, greater than or equal to 300 mm, greater than or equal to 400 mm) to prevent defects (e.g., propagating cracks, from forming in the glass substrate 232 as a result of cold-forming.

As shown in FIG. 2, the OLED display module 240 is also curved such that the front surface 244 extends parallel (or within 10° of parallel) to the first major surface 234. The glass substrate 232 and the OLED display module 240 are depicted to be curved along a widthwise direction (e.g., a first direction) of the glass substrate 232. It should be appreciated that a variety of curved configurations for the glass substrate 232 and the OLED display module 240 are contemplated and within the scope of the present disclosure. In embodiments, for example, the glass substrate 232 and the OLED display module 240 are curved along a lengthwise direction of the glass substrate 232 (e.g., a second direction perpendicular to the first direction). The glass substrate 232 and the OLED display module 240 may be curved along various combinations of directions to form a variety of geometric profiles. In the embodiment depicted in FIGS. 1-2, entireties of the glass substrate 232 and the OLED display module 240 are curved with uniform radii of curvature. Embodiments where the glass substrate 232 and the OLED display module 240 include non-uniform distributions of curvature (or where portions of the glass substrate 232 and the OLED display module 240 are not curved) are also contemplated and within the scope of the present disclosure.

As used herein, the phrase “curved along,” when used to describe a particular direction of curvature of a surface, refers to a direction of a line tangent to the surface that the referenced curvature causes the surface to deviate from. As a result of the curvature, the surface may include a radius of curvature that is measured from a point on a line extending perpendicular to the direction along which the surface is curved. In an example, a surface that is curved along the X-direction may possess a radius of curvature measured from a line extending in the Y-direction.

In embodiments, the OLED display module 240 is constructed of relatively flexible components such that the OLED display module 240 can be manipulated in shape via application of external forces thereto to facilitate cold-forming. As described herein with respect to FIG. 3, for example, the OLED display module 236 may be constructed of a plurality of functional layers formed of a relatively flexible material (e.g., having Young's moduli of 10 GPa or less) and have an overall device thickness of less than or equal to 2 mm (e.g., less than or equal to 1 mm, less than or equal to 0.5 mm). Such a flexible construction of the OLED display module 240 may advantageously permit the OLED display module 240 to be formed in an initial (e.g., non-curved or planar) configuration and manipulated to conform to the curved glass substrate 232 when integrated into the OLED display 230 via cold-forming techniques. Such techniques lower production costs by reducing the need to initially fabricate display components in a curved configuration and also permit flexibility in terms of display component use.

In embodiments, the glass substrate 232 and the OLED display module 240 are placed into the curved configuration depicted in FIG. 2 using cold-forming or cold-bending techniques. By “cold-forming” or “cold-bending,” it is meant that at least portions of the glass substrate 232 and the OLED display module 240 are manipulated in shape via application of an external force thereto when the glass substrate 232 and the OLED display module 240 are at a temperature beneath a softening temperature of the glass substrate 232. For example, in embodiments, cold-forming of the glass substrate 232 and the OLED display module 240 takes place at below 200° C., below 100° C., or even at room temperature. In embodiments, during cold-forming, pressure is applied to the glass substrate 232 and/or OLED display module 240 to bring the glass substrate 232 and/or OLED display module 240 into conformity with a chuck, mold, or other support structure configured to support the glass substrate 232 and/or OLED display module 240 in a desired curved configuration (e.g., via a curved surface), such as the shape depicted in FIGS. 1-2. The pressure may be applied in a variety of different ways, such as via suction or vacuum, a mechanical press, rollers, etc.

Once placed into a curved configuration, the glass substrate 232 and/or OLED display module 240 may be held in the curved configuration via attachment to a support structure 245. The support structure 245 is mechanically coupled to at least one of the glass substrate 232 and the OLED display module 240 so as retain the glass substrate 232 and OLED display module 240 in a curved configuration originating from the bending force applied thereto during cold-forming. In embodiments, the support structure 245 is adhered directly to the first major surface 234, the second major surface 236, the minor surface 238, and/or the OLED display module 240 via an adhesive or other suitable attachment mechanism. In embodiments, the support structure 245 is indirectly attached to the glass substrate 232 and OLED display module 240 via an intermediate element. As such, the phrase “mechanically coupled,” as used herein, encompasses any mode of mechanical connection between the glass substrate 232, OLED display module 240, and support structure 245.

The support structure 245 may include a flexural rigidity that is greater than that of the glass substrate 232 and the OLED display module 240 and be configured to hold components of the OLED display 230 to retain the glass substrate 232 and the OLED display module 240 in a desired configuration. The support structure 245 may take a variety of forms depending on the implementation and be attached to various components of the OLED display 230 in a variety of different ways. In the depicted embodiment, for example, the support structure 245 is a frame that circumferentially surrounds the OLED display module 240 and is attached to the glass substrate 232 via the minor surface 238 (e.g., the support structure 245 may include a plurality of grooves into which peripheral edges of the glass substrate 232 are inserted, and the grooves may follow a curved profile to retain the glass substrate 232 and OLED display module 240 in the curved configuration). In embodiments, the support structure 245 comprises one or more structure members disposed on the second major surface 236 of the glass substrate 232. For example, in embodiments, the support structure 245 comprises a frame adhered to a peripheral region of the second major surface 236 (the OLED display module 240 may be attached to a central region of the second major surface 236 via the attachment adhesive layer 242 such that the OLED display module 240 is surrounded by the frame). In such embodiments, the support structure 245 is constructed of a material that is more structurally rigid (e.g., possess a greater flexural rigidity) than the glass substrate 232. The support structure 245 may possess a curvature independent of the bending force applied to the glass substrate 232 and the OLED display module 240. As a result, attachment between the support structure 245 and the glass substrate 232 may retain the glass substrate 232 and OLED display module 240 in a curved configuration.

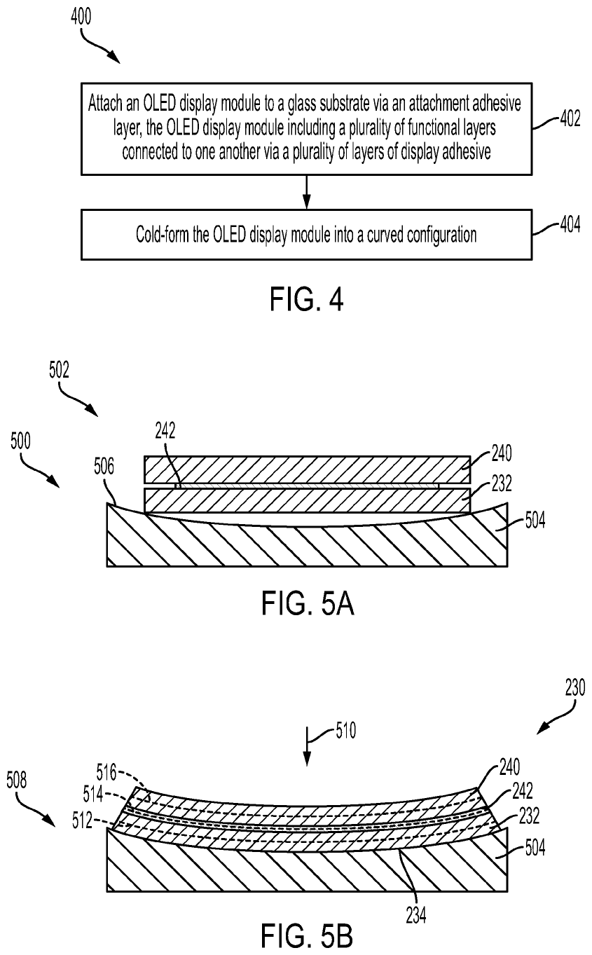

It should be understood that the present disclosure is not limited to any particular method of cold-forming or cold bending and that the particular form and structural relationship between the support structure 245, glass substrate 232, and OLED display module 240 may vary depending on the cold-forming technique employed. Moreover, different sequences of cold-forming the glass substrate 232 and the OLED display module 240 are contemplated and within the scope of the present disclosure, as described herein with respect to FIGS. 4-6B. In embodiments, the OLED display module 240 may be attached to the glass substrate 232 prior to or after the glass substrate 232 being curved formed. For example, in embodiments, the OLED display module 240 is adhered to the second major surface 236 via the attachment adhesive layer 242 when the glass substrate 232 and OLED display module 240 are in an un-curved (e.g., planar) configuration to form an OLED display stack. The OLED display stack may then be cold-formed into the curved configuration depicted in FIG. 2 using a variety of different techniques. In embodiments, for example, an external force (e.g., via a vacuum, mold, or roller) may be applied to the OLED display stack to place a portion of the stack (e.g., the first major surface 234) in contact with a surface (e.g., of a chuck or mold) possessing a curvature and then attaching the support structure 245 to the second major surface 236 to retain the stack in a curved configuration.

In embodiments, cold-forming the display stack may involve any of the techniques described in U.S. Pre-Grant Publication No. 2019/0329531 A1, entitled “Laminating thin strengthened glass to curved molded plastic surface for decorative and display cover application,” U.S. Pre-Grant Publication No. 2019/0315648 A1, entitled “Cold-formed glass article and assembly process thereof,” U.S. Pre-Grant Publication No. 2019/0012033 A1, entitled “Vehicle interior systems having a curved cover glass and a display or touch panel and methods for forming the same,” and U.S. patent application Ser. No. 17/214,124, entitled “Curved glass constructions and methods for forming same,” which are hereby incorporated by reference in their entireties.

Cold-forming provides certain advantages for assembling the OLED displays according to the present disclosure. In particular, the low temperature at which the cold-forming is conducted may make the process less expensive than conventional hot-forming processes (e.g., where the glass substrate 232 and components of the OLED display module 240 are initially fabricated in a curved configuration). Further, the temperatures associated with hot-forming processes have been known to thermally disrupt or degrade surface treatments or create optical distortions. For this reason, surface treatments were generally applied to curved glass articles, which increased the complexity of the surface treatment application process. Because cold-forming is done at much lower temperatures than conventional hot-forming, the surface treatments can be applied while the glass substrate is in a planar configuration without the concern that the bending operation will cause thermal disruption or degradation of the surface treatment.

The process of cold-forming the glass substrate 232 and the OLED display module 240 may result in a distribution of bending-induced strain being placed on the OLED display 230. That is, the glass substrate 232 and the OLED display module 240 may be retained by the support structure 245 in a state of persistent strain. Such persistent strain may lead to mechanical instability of the OLED display 230, creating the potential for mechanical failure (e.g., breakage, deconstruction, delamination, crack propagation) of the OLED display 230.

The potential for bending strain-induced failure of the OLED display 230 from the cold-forming may be understood more completely in view of structure of the OLED display module 240. FIG. 3 schematically depicts a cross-sectional view of the OLED display 230 through the line III-III of FIG. 2, according to an example embodiment. As shown, the OLED display module 240 includes a plurality of functional layers 246a, 246b, . . . 246x that are connected to one another via a plurality of layers of display adhesive 248a, 248b, . . . 248y. Each of the plurality of functional layers 246a, 246b, . . . 246x may include or contain one or more functional components of the OLED display 230. The OLED display module 240 may include any number of functional layers, depending on the implementation. For example, in embodiments, the plurality of functional layers 246a, 246b, . . . 246x includes one or more of, with increasing distance from the glass substrate 232, a polarization layer (e.g., including a circular polarizer), a touch-sensitive layer (e.g., including a multi-layer stack), a display layer (e.g., including a polymer substrate, thin film transistors, an OLED layer, and encapsulation layers), and a backplate layer. In embodiments, a first functional layer 246a of the plurality of functional layers 246a, 246b, . . . 246x is a glass cover that is adhered to glass substrate 232. In embodiments, the first functional layer 246a comprises a layer of polymeric material and functions as a circular polarizer.

While each of the plurality of functional layers 246a, 246b, . . . 246x is depicted as being a single layer, it should be appreciated that each of the plurality of functional layers 246a, 246b, . . . 246x may include multiple sub-layers, with each sublayer having different properties (e.g., material, thickness). Certain ones of the plurality of functional layers 246a, 246b, . . . 246x may include multiple functional components of the OLED display. For example, in embodiments, one of the plurality of functional layers 246a, 246b, . . . 246x includes both an OLED display layer and a touch-sensitive layer.

The plurality of layers of display adhesive 248a, 248b, . . . 248y may each include an adhesive that attaches adjacent ones of the plurality of functional layers 246a, 246b, . . . 246x to one another. In embodiments, the adhesive in each of the plurality of layers of display adhesive 248a, 248b, . . . 248y can include an optically clear adhesive and/or a pressure sensitive adhesive. In embodiments, the adhesive can comprise an optically clear adhesive comprising a polymer (e.g., optically transparent polymer). Exemplary optically clear adhesives can include, but are not limited to acrylic adhesives (e.g., 3M 821x adhesive, with x representing the thickness of the OCA in mils), an optically transparent liquid adhesive (e.g., a LOCTITE optically transparent liquid adhesive), and transparent acrylics, epoxies, silicones, and polyurethanes. In embodiments, one or more of the plurality of layers of display adhesive 248a, 248b, . . . 248y can comprise one or more of a silicone-based polymer, an acrylate-based polymer, an epoxy-based polymer, a thiol-containing polymer, or a polyurethane. In embodiments where one or more of the plurality of layers of display adhesive 248a, 248b, . . . 248y includes a silicone-based polymer, the silicone-based polymer can comprise a silicone elastomer. Exemplary embodiments of a silicone elastomer include PP2-OE50 available from Gelest and LS 8941 available from NuSil. In embodiments, one or more of the plurality of layers of display adhesive 248a, 248b, 248y may include an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In embodiments, one or more of the plurality of layers of display adhesive 248a, 248b, . . . 248y includes a sol-gel material. In embodiments, one or more of the plurality of layers of display adhesive 248a, 248b, . . . 248y includes an ethylene acid copolymer. An exemplary embodiment of an ethylene acid copolymer includes SURLYN available from Dow (e.g., Surlyn PC-2000, Surlyn 8940, Surlyn 8150). An additional exemplary embodiment for the second portion comprises Eleglass w802-GL044 available from Axalta with from 1 wt % to 2 wt % cross-linker. Each of the preceding materials in this paragraph may also be incorporated into the attachment adhesive layer 242.

In embodiments, each one of the plurality of layers of display adhesive 248a, 248b, 248y directly contacts and adheres to at least one (e.g., on the ends of the OLED display module 240) or two of the plurality of functional layers 246a, 246b, . . . 246x. As a result, the OLED display 230 includes a plurality of adhesive layers, including the attachment adhesive layer 242 and the plurality of layers of display adhesive 248a, 248b, . . . 248y. In embodiments, the OLED display 230 includes n adhesive layers, with n being greater than or equal to 2 (e.g., greater than or equal to 3, greater than or equal to 4, greater than or equal to 5). While each the plurality of layers of display adhesive 248a, 248b, . . . 248y are depicted to include a similar thickness, it should be understood that each layer of display adhesive may differ from one another in size, thickness, and composition in accordance with the present disclosure.

In embodiments, each of the plurality of layers of display adhesive 248a, 248b, . . . 248y may have a thickness of 10 μm or more, 25 μm or more, 40 μm or more, 65 μm or more, 1 mm or less, 2 mm or less, 1 mm or less, 500 μm or less, 250 μm or less, 200 μm or less, 150 μm or less, 125 μm or less, 100 μm or less, or 80 μm or less. In embodiments each of the plurality of layers of display adhesive 248a, 248b, . . . 248y may have a thickness in a range from 10 μm to 2 mm, from 10 μm to 1 mm, from 10 μm to 500 μm, from 10 μm to 250 μm, from 10 μm to 200 μm, from 10 μm to 150 μm, from 10 μm to 125 μm, 10 μm to 100 μm, from 25 μm to 100 μm, from 40 μm to 100 μm, from 65 μm to 100 μm, from 65 μm to 80 μm, or any range or subrange therebetween. The attachment adhesive layer 142 may also a thickness lying in any of the aforementioned ranges.

Referring now to FIGS. 2-3, as described herein, the components of the OLED display module 240 (e.g., each of the plurality of functional layers 246a, 246b, . . . 246x) may be constructed of a material having a flexural rigidity or Young's modulus that is significantly less than that of the glass substrate 232. For example, in embodiments, at least some of the plurality of functional layers 246a, 246b, . . . 246x are constructed of a polymeric material such as polyimides, styrene-based polymers (e.g., polystyrene (PS), styrene acrylonitrile (SAN), styrene maleic anhydride (SMA)), phenylene-based polymer (e.g., polyphenylene sulfide (PPS)), polyvinylchloride (PVC), polysulfone (PSU), polyphthalmide (PPA), polyoxymethylene (POM), polylactide (PLA), polyimides (PI), polyhydroxybutyrate (PHB), polyglycolides (PGA), polyethyleneterephthalate (PET), and/or polycarbonate (PC). In embodiments, each of the plurality of functional layers 246a, 246b, . . . 246x comprises a thickness of less than or equal to 500 μm (e.g., less than or equal to 200 μm, less than or equal to 100 μm).

In embodiments, the glass substrate 232 is constructed from a glass composition having a Young's modulus that is greater than or equal to 60 GPa, (e.g., greater than or equal to 65 GPa, greater than or equal to 66 GPa, greater than or equal to 67 GPa, greater than or equal to 68 GPa, greater than or equal to 69 GPa). In embodiments, the glass substrate 232 may also include a thickness T1 that is greater than or equal to 0.6 mm and less than or equal to 1.2 mm). More details of the structure and composition of the glass substrate 232 according to various embodiments is provided herein with respect to FIG. 7.

In embodiments, each of the glass substrate 232 and the plurality of functional layers 246a, 246b, . . . 246x of the OLED display module comprises a minimum aspect ratio (equal to a width of the component divided by the component's thickness, W1/T1 for the glass substrate 232—see FIG. 7) that is greater than or equal to 15. As a result, when using Kirchhoff-Love plate theory to estimate bending strains placed on each of the glass substrate 232 and the plurality of functional layers 246a, 246b, . . . 246x, each layer may be considered a thin shell, where the positioning of a neutral plane within each layer is independent of the shape of the layer. Consider an example where the OLED display module 240 is a homogenous layer having a Young's modulus E₁ and a thickness t₁ and the glass substrate 232 includes a Young's modulus E₂ and a thickness t₂. In a case where the OLED display 230 is approximated as a composite plate (representing an illustrative example where the OLED display module 240 is perfectly adhered to the glass substrate 232), the positioning of a neutral plane, representing a surface of zero strain within a bending strain distribution, may be calculated as

$$\overline{y} = \frac{{\sum }_{i = 1}^{2} {\overline{y}}_{i} {A}_{i}}{{\sum }_{i = 1}^{2} {A}_{i}} = \frac{\frac{{t}_{1}}{2} b {t}_{1} + ( {t}_{1} + \frac{{t}_{2}}{2} ) n b {t}_{2}}{b {t}_{1} + n b {t}_{2}} \qquad ( 1 )$$

Where Aᵢ is the cross-sectional area of each layer, n=E₂/E₁ and b is a length of the layers along perpendicular to the direction of curvature causing the bending strain (e.g., corresponding to the dimension W depicted in FIG. 2). In this example, with a sample size (b value) of 200 mm and where the glass substrate 232 is a 1 mm thick sheet of a glass having a Young's modulus of 70 GPa, and the OLED display module is a 1 mm thick sheet of PET (having a Young's modulus of 2.95 GPa). the neutral axis would be at a position of only 0.004 mm from a center of the glass substrate 232. According to Kirchhoff-Love shell theory, the bending stress at a particular location within a plate may be calculated as

$$ε = \frac{y}{R} , \qquad ( 2 )$$

and the bending strain at a particular location within a plate may be calculated as

$$σ = \overline{E} \frac{y}{R} \qquad ( 3 )$$

where

$$\overline{E} = \frac{E}{1 - {v}^{2}} \qquad ( 4 )$$

and R is bend radius, y is the distance from the neutral plane (calculated using equation 1 above), and ν is the Poisson's ratio of the material of the plate.

In view of the foregoing, if the adhesive layers of the display panel 230 (the attachment adhesive layer 242 and the plurality of layers of display adhesive 248a, 248b, . . . 248y) are selected such that the bending strain distributions in glass substrate 232 and the OLED display module 240 are not decoupled from one another, the plurality of functional layers 246a, 246b, . . . 246x of the OLED display module 240 may be subjected to significant bending strain, as the neutral plane would be located within the glass substrate 232, resulting in the distance y in equation 2 above being relatively large (e.g., at least half the thickness of the glass substrate 232). Such high bending strain may render mechanical failure of the OLED display 230 likely over the course of the lifetime of the OLED display 230.

To aid in reducing the amount of residual bending strain retained in the plurality of functional layers 246a, 246b, . . . 246x as a result of the cold-forming, properties of the attachment adhesive layer 242 and the plurality of layers of display adhesive 248a, 248b, . . . 248y may be select to provide decoupling of bending strain distributions in layers of the OLED display 230. That is, the bending strain distribution retained in the OLED display module 240 may contain at least two neutral planes, with each neutral plane representing a surface of zero bending strain. In embodiments, the attachment adhesive layer 242 and the plurality of layers of display adhesive 248a, 248b, . . . 248y are selected such that the OLED display 230 includes m=2n+1 neutral planes after cold-forming, where n equals the number of adhesive layers in the OLED display panel (equal to the number of layers in the plurality of layers of display adhesive 248a, 248b, . . . 248y and the number of layers in the layer of display adhesive 242). As a result, each layer in the OLED display 230 may contain a neutral plane of the bending strain distribution. As shown in FIG. 3, for example, the bending strain distribution as a result of cold-forming the OLED display 230 includes a plurality of neutral planes 250a, 250b, 250c, 250d, 250e, 250m−1, . . . 250m. Each one of the plurality of neutral planes 250a, 250b, 250c, 250d, 250e, 250m−1, . . . 250m is depicted to be located in one of the layers of the OLED display module 230 (e.g., a first neutral plane 250a is located in the glass substrate 232, a second neutral plane 250b is located in the attachment adhesive layer 242, a third neutral plane 250c is located in a first functional layer 246a of the OLED display module 240, and so on). Such a construction beneficially reduces the peak bending strain applied to each layer of the OLED display 230, as the variable y in equation 2 above is limited to the thickness of each particular layer.

Applicant has determined that adhesive layers that are relatively compliant (e.g., formed of material having a relatively low Young's modulus) aid in decoupling the bending strain distributions in each of the plurality of functional layers 246a, 246b, . . . 246x and the glass substrate 232 from one another. Additionally, it has been determined that increasing the thickness of the adhesive layers also aids in decoupling the bending strain distributions located in each layer of the OLED display 230. In embodiments, for example, each adhesive layer in the OLED display module is constructed of a material having a Young's modulus that is at most 1/1000 times (e.g., at most 1/2000 times, at most 1/5000 times, at most 1/10000 times, at most 1/100000 times, at most 1/500000 times) the Young's moduli of the layers adjacent to that adhesive layer. To illustrate, the attachment adhesive layer 142 may be constructed of a material that is at most 1/1000 times (e.g., at most 1/2000 times, at most 1/5000 times, at most 1/10000 times, at most 1/100000 times, at most 1/500000 times) the Young's modulus of the glass substrate 232 and at most 1/1000 times (e.g., at most 1/2000 times, at most 1/5000 times, at most 1/10000 times, at most 1/100000 times, at most 1/500000 times) the Young's modulus of the first functional layer 246a. In embodiments, each of the plurality of adhesive layers (that is, each of the plurality of layers of display adhesive 248a, 248b, . . . 248y and the attachment adhesive layer 142) has a Young's modulus that is greater than or equal to 0.5 kPa and less than or equal to 1.5 MPa.

In embodiments, the Young's modulus and thickness of each adhesive layer in the OLED display 230 are selected based on the structure and composition of the totality of the OLED display 230 (e.g., the thickness and material properties of each layer in the OLED display 230). According to the model described in pages 3-7 of the article entitled “Splitting of the neutral mechanical plane depends on the length of the multi-layer structure of flexible electronics,” Proc. R. Soc. A 472 (2016), hereby incorporated by reference in its entirety, the positioning of the neutral planes as a result of bending a multi-layer stack of material depends on the elastic properties of each layer in the stack, the thickness of each layer in the stake, the radius of curvature to which the stack is bent, and the dimensions of the sample along the direction of curvature. As such, in this particular example, the particular properties of each adhesive layer needed to split the neutral planes may vary depending on the material properties of the glass substrate 232 and the plurality of functional layers 246a, 246b, . . . 246x, the radius of curvature R, and the dimension W the portion of each layer being bent to the radius of curvature R.

In embodiments, the attachment adhesive layer 242 and the plurality of layers of display adhesive 248a, 248b, . . . 248y are constructed of materials having a Young's modulus that is less than or equal to 0.5 MPa (e.g., less than or equal to 0.4 MPa, less than or equal to 0.3 MPa, less than or equal to 0.2 MPa, less than or equal to 0.1 MPa, less than or equal to 0.05 MPa) and have a thickness that is greater than or equal to 0.1 mm (e.g., greater than or equal to 0.2 mm, greater than or equal to 0.3 mm, greater than or equal to 0.4 mm, greater than or equal to 0.5 mm, greater than or equal to 0.6 mm, greater than or equal to 0.7 mm, greater than or equal to 0.8 mm, greater than or equal to 0.9 mm, greater than or equal to 1.0 mm). In embodiments, when the thickness of a particular adhesive layer is relatively large (e.g., greater than or equal to 0.7 mm), the Young's modulus needed to separate the neutral planes may also be relatively high.

In embodiments, the dimension of the OLED display 230 along the direction of curvature (the W in this example) is greater than or equal to 100 mm (e.g., greater than or equal to 200 mm, greater than or equal to 300 mm, greater than or equal to 400 mm, greater than or equal to 500 mm, greater than or equal to 600 mm, greater than or equal to 700 mm, greater than or equal to 800 mm, greater than or equal to 900 mm, greater than or equal to 1.0 m, greater than or equal to 1.5 m, greater than or equal to 2.0 m). It has been found that the propensity of the neutral plane splitting phenomenon described herein is inversely proportional to the dimensional size of the display along the direction of curvature from the bending Increased length of the display along the direction of curvature has been found to inhibit neutral plane splitting. Accordingly, as the portion of the OLED display that is curved increases in size, more compliant adhesive layers (e.g., having Young's moduli lower than 0.1 MPa and thicknesses greater than or equal to 0.5 mm) may be needed to split the neutral planes. For relatively large OLED displays, having a length or width along a direction of curvature of 500 mm or more, adhesive layers having Young's moduli of less than 0.07 MPa and thicknesses greater than 0.7 mm may be beneficial. Displays having lengths or widths along a direction of curvature of more than 1.0 m may benefit from even more compliant adhesive layers (e.g, having Young's moduli less than or equal to 0.04 MPa and thicknesses of greater than or equal to 1.0 m).

It should be understood that the adhesive layers within the OLED display 230 may differ one another in terms of properties while still achieving the neutral plane splitting depicted in FIG. 3. For example, due to proximity to the relatively rigid glass substrate 232, the attachment adhesive layer 242 may have a flexural rigidity that is less than the plurality of layers of display adhesive 248a, 248b, . . . 248y to split the neutral planes. In embodiments, the flexural rigidity of each adhesive layer increases with increasing distance from the glass substrate 232. In embodiments, for example, the attachment adhesive layer 242 may have a thickness that is greater and/or a Young's modulus that is less than that of the layer of display adhesive 248y that is most distant from the glass substrate 232. Such a construction may beneficially aid in rendering the OLED display 230 as compact as possible. In embodiments, each layer of adhesive in the display module 230 may have a maximum flexural rigidity to split the neutral plane into m=2n+1 neutral planes in order to maximize the flexural strength of the OLED display 230 while still retaining the strain distribution benefits described herein.

The presence of a plurality of neutral planes within a cold-formed glass article may be determined analytically based on the structure of the article using finite element analysis or may be physically measured. In a constructed OLED display, an image correlation technique, such as the one described in the “Study of Deformation Behavior of Multilayered Sheets Using Digital Image Correlation,” Procedia Manufacturing 47 (2020), 1257-1263, hereby incorporated reference in its entirety, may be used to measure the displacement field to determine the bending strain distribution. The presence of a neutral plane may also be determined analytically using a suitable finite element model using the elastic properties (e.g, Young's modulus and Poisson's ratio) thickness, length, width, and bending radius of each layer as an input. Proper displacement boundary conditions can be imposed to drive the specimen bent to the bending radius to generate a bend strain distribution to determine the location of the neutral planes.

As described herein, the present disclosure is not limited to any particular cold-forming method, structure, or sequence. Any structure where an OLED display is bent from a neutral position and retained in a condition of residual strain as a result of the bending is within the scope of the present disclosure. Moreover, while the example described herein with respect to FIGS. 1-3 relates to embodiments where an OLED display module 240 is adhered directly to a major surface of a glass substrate 232, the present disclosure is not limited to such embodiments. Embodiments where there is an airgap present between the OLED display module and the glass substrate, for example, are contemplated and within the scope of the present disclosure. In such embodiments, the OLED display module may be structured to contain n adhesive layers, and m=2n+1 neutral planes as a result of the cold-forming.

Referring now to FIG. 4, a flow diagram of a method 400 of attaching an OLED display module to a glass substrate and cold-forming the OLED display module is depicted. In an example, the method 400 may be performed to construct the OLED display 230 described herein with respect to FIGS. 1-3 prior to installation in a vehicle. Accordingly, reference will be made to various components of the OLED display 230 depicted in FIGS. 2-3 to aid in the description of the method 400. It should be understood that the method 400 may be used to form a variety of OLED displays for incorporation into vehicle interior systems. Moreover, various process steps (e.g., treatments of the glass substrate, polishing, shaping, etc.) have been omitted for purposes of discussion.

At block 402, the OLED display module 240 is attached to the glass substrate 232 via the attachment adhesive layer 242. The OLED display module 240 may include a structure that is specifically designed based on a desired geometry (e.g., dimensions, curvatures) of the OLED display module 230 after cold-forming. For example, the plurality of layers of display adhesive 248a, 248b, . . . 248y may have material properties and thicknesses that are selected to generate a bending strain distribution containing a plurality of neutral planes, with each of the neutral planes lying in a separate layer of the OLED display module after the cold-forming In embodiments, each plurality of layers of display adhesive 248a, 248b, . . . 248y and the attachment adhesive layer 242 includes a Young's modulus and thickness selected based on or more of the dimension W of the OLED display 230 along a direction of curvature, material properties (e.g., thickness, Young's modulus) of the glass substrate 232, the radius of curvature R to which the OLED display module 240 is to be bent to correspond to, and the construction/arrangement of the plurality of functional layers, 246a, 246b, . . . 246x. In embodiments, a finite element analysis simulation may be conducted to determine properties of each plurality of layers of display adhesive 248a, 248b, . . . 248y and the attachment adhesive layer 242 to provide the neutral plane splitting.

At block 404, the OLED display module 240 is cold-formed into a curved configuration. In embodiments, as described herein with respect to FIGS. 2-3, the glass substrate 232 is cold-formed such that the first major surface 234 is curved at a radius of curvature R and the OLED display module 240 is cold-formed against the second major surface 236 of the glass substrate 232 such that the front surface 244 has a curvature that matches or substantially matches that of the second major surface 236. Embodiments are also envisioned where the glass substrate 232 is not cold-formed and instead hot-formed (e.g., via sagging or other suitable technique) to possess a curved shape, and the OLED display module 240 is cold-formed against the glass substrate 232 to be held and retained against the second major surface 236 in a corresponding curved configuration.

In embodiments, the attachment of the glass substrate 232 to the OLED display module 240 may occur before or after the glass substrate 232 is cold-formed. The OLED display module 240 and the glass substrate 232 may be cold-formed at the same time (e.g., in the same process step using the same hardware) or at different times (e.g., at different steps and/or using different hardware), depending on the implementation. For example, FIGS. 5A-5B schematically depict cross-sectional views of the OLED display 230 during various stages of a cold-forming process, according to an example embodiment. At a step 500, the OLED display module 240 is adhered to the glass substrate 232 via the attachment adhesive layer 242 pre-cold-forming to form a non-curved display stack 502 (the attachment adhesive layer 242 may be cured while the glass substrate 232 and OLED display module 240 are in a non-curved state). As depicted in FIG. 5A, the non-curved display stack 502 may be aligned with a forming structure 504 (e.g., a chuck, mold, or other suitable structure) including a curved surface 506. In embodiments, the curved surface 506 includes a geometry desired of the first major surface 234 (see FIG. 2) of the glass substrate 232 after cold-forming.

As shown in FIG. 5B, at a step 508, after alignment with the forming structure 504, a bending force is applied to one or more of the glass substrate 232 and the OLED display panel 240 along a direction of the arrow 510 to bring at least a portion of the first major surface 234 into contact with the curved surface 506, thereby bending the glass substrate 232 and the OLED display module 240. The bending force may be applied using any suitable technique (e.g, vacuum, mold, distribution of actuators). The bending of the glass substrate 232 and the OLED display module 240 is depicted to generate three (3) neutral planes 512, 514, 516 as a result of the flexural rigidity of each of the glass substrate 232, the attachment adhesive layer 242, and the OLED display module 240. In embodiments, the neutral plane 516 comprises a plurality of sub-neutral planes (not depicted), with each sub-neutral plane extending through one of the component layers (one of the plurality of layers of display adhesive 248a, 248b, . . . 248y and the plurality of functional layers 246a, 246b, . . . 246x). As a result of the structure of the adhesive layers in the OLED display 230, the bending strain distributions as a result of the bending force are split. A suitable support structure may be attached to any portion of the OLED display panel 230 to retain the OLED display 230 in a desired curved shape.

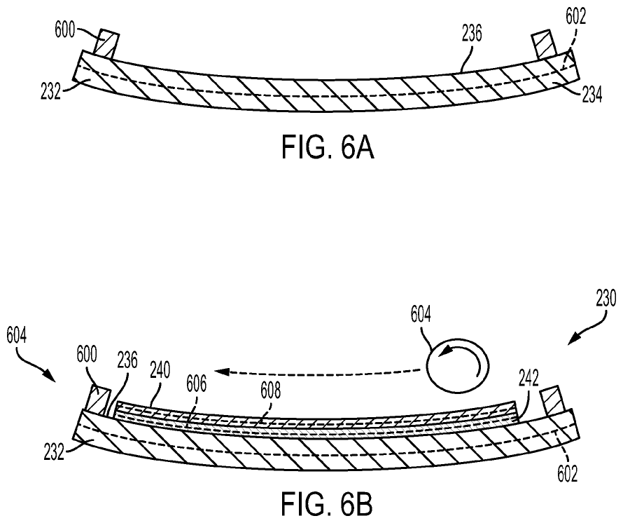

FIGS. 6A-6B schematically depict cross-sectional views of another process by which the OLED display panel 230 of FIGS. 2-3 may be fabricated. FIG. 6A schematically depicts the glass substrate 232 in a pre-cold-formed state. As shown, a support structure 600 (e.g, a rigid frame, a plurality of separate support structures) is attached to the glass substrate 232 and is configured to retain the glass substrate 232 in the depicted curved configuration. While the support structure 600 is depicted to be disposed on the second major surface 236, it should be understood that the support structure 600 may be adhered to any surface of the glass substrate 232. The support structure 600 may function in a manner similar to the support structure 245 described herein with respect to FIG. 2 and be adhered to the glass substrate 232 using similar techniques. As shown, the cold-forming of the glass substrate 232 results in bending strain distribution within the glass substrate 232 having a neutral plane 602.

As shown in FIG. 6B, after the glass substrate 232 is cold-formed, the attachment adhesive layer 242 and the OLED display module 240 may be sequentially laminated onto the second major surface 236 of the glass substrate 232. In embodiments, the attachment adhesive layer 242 is initially laminated onto the second major surface 246, followed by the OLED display module 240 using any suitable technique. For example, a roller 604 may be used to laminate the attachment adhesive layer 242 and the OLED display module 240 onto the glass substrate 232. The attachment adhesive layer 242 may then be cured such that the OLED display panel 240 is retained in the curved configuration. Two additional neutral planes 606 and 608 may form as a result of retained bending strain from the OLED display module 240 being retained in a non-equilibrium state. In embodiments, the neutral plane 608 comprises a plurality of sub-neutral planes (not depicted), with each sub-neutral plane extending through one of the component layers (one of the plurality of layers of display adhesive 248a, 248b, . . . 248y and the plurality of functional layers 246a, 246b, . . . 246x). As a result of the structure of the adhesive layers in the OLED display 230, the bending strain distributions as a result of the bending force are split. A suitable support structure may be attached to any portion of the OLED display panel 230 to retain the OLED display 230 in a desired curved shape.

As demonstrated by the examples described with respect to FIGS. 5A-6B, the neutral planes contained in the OLED display panels described herein may be formed in a variety of different processes and sequences. The present disclosure is not limited to any particular cold-forming technique. Any OLED display where portions of OLED components are manipulated from a strain-free condition and possess a retained bending strain are within the scope of the present disclosure. The cold-formed OLED components may not be directly adhered to a glass substrate, but rather adhered to a support structure (e.g., frame) in alignment with a glass substrate.

### Glass Substrate Properties

In the following paragraphs, various geometrical, mechanical, and strengthening properties of the glass substrate 232 as well as compositions of the glass substrate 232 are provided. Referring to FIG. 7, the glass substrate 232 has a thickness T1 that is substantially constant over the width and length of the glass substrate 232 and is defined as a distance between the first major surface 234 and the second major surface 236. In various embodiments, T1 may refer to an average thickness or a maximum thickness of the glass substrate 232. In addition, the glass substrate 232 includes a width W1 defined as a first maximum dimension of one of the first or second major surfaces 234, 236 orthogonal to the thickness T1, and a length L1 defined as a second maximum dimension of one of the first or second major surfaces 234, 236 orthogonal to both the thickness and the width. In other embodiments, W1 and L1 may be the average width and the average length of the glass substrate 232, respectively, and in other embodiments, W1 and L1 may be the maximum width and the maximum length of the glass substrate 232, respectively (e.g., for glass substrates 232 having a variable width or length).

In various embodiments, thickness T1 is 2 mm or less. In particular, the thickness T1 is from 0.30 mm to 2.0 mm. For example, thickness T1 may be in a range from about 0.30 mm to about 2.0 mm, from about 0.40 mm to about 2.0 mm, from about 0.50 mm to about 2.0 mm, from about 0.60 mm to about 2.0 mm, from about 0.70 mm to about 2.0 mm, from about 0.80 mm to about 2.0 mm, from about 0.90 mm to about 2.0 mm, from about 1.0 mm to about 2.0 mm, from about 1.1 mm to about 2.0 mm, from about 1.2 mm to about 2.0 mm, from about 1.3 mm to about 2.0 mm, from about 1.4 mm to about 2.0 mm, from about 1.5 mm to about 2.0 mm, from about 0.30 mm to about 1.9 mm, from about 0.30 mm to about 1.8 mm, from about 0.30 mm to about 1.7 mm, from about 0.30 mm to about 1.6 mm, from about 0.30 mm to about 1.5 mm, from about 0.30 mm to about 1.4 mm, from about 0.30 mm to about 1.4 mm, from about 0.30 mm to about 1.3 mm, from about 0.30 mm to about 1.2 mm, from about 0.30 mm to about 1.1 mm, from about 0.30 mm to about 1.0 mm, from about 0.30 mm to about 0.90 mm, from about 0.30 mm to about 0.80 mm, from about 0.30 mm to about 0.70 mm, from about 0.30 mm to about 0.60 mm, or from about 0.30 mm to about 0.40 mm. In other embodiments, the T1 falls within any one of the exact numerical ranges set forth in this paragraph.

In various embodiments, width W1 is in a range from 5 cm to 250 cm, from about 10 cm to about 250 cm, from about 15 cm to about 250 cm, from about 20 cm to about 250 cm, from about 25 cm to about 250 cm, from about 30 cm to about 250 cm, from about 35 cm to about 250 cm, from about 40 cm to about 250 cm, from about 45 cm to about 250 cm, from about 50 cm to about 250 cm, from about 55 cm to about 250 cm, from about 60 cm to about 250 cm, from about 65 cm to about 250 cm, from about 70 cm to about 250 cm, from about 75 cm to about 250 cm, from about 80 cm to about 250 cm, from about 85 cm to about 250 cm, from about 90 cm to about 250 cm, from about 95 cm to about 250 cm, from about 100 cm to about 250 cm, from about 110 cm to about 250 cm, from about 120 cm to about 250 cm, from about 130 cm to about 250 cm, from about 140 cm to about 250 cm, from about 150 cm to about 250 cm, from about 5 cm to about 240 cm, from about 5 cm to about 230 cm, from about 5 cm to about 220 cm, from about 5 cm to about 210 cm, from about 5 cm to about 200 cm, from about 5 cm to about 190 cm, from about 5 cm to about 180 cm, from about 5 cm to about 170 cm, from about 5 cm to about 160 cm, from about 5 cm to about 150 cm, from about 5 cm to about 140 cm, from about 5 cm to about 130 cm, from about 5 cm to about 120 cm, from about 5 cm to about 110 cm, from about 5 cm to about 110 cm, from about 5 cm to about 100 cm, from about 5 cm to about 90 cm, from about 5 cm to about 80 cm, or from about 5 cm to about 75 cm. In other embodiments, W1 falls within any one of the exact numerical ranges set forth in this paragraph.

In various embodiments, length L1 is in a range from about 5 cm to about 2500 cm, from about 5 cm to about 2000 cm, from about 4 to about 1500 cm, from about 50 cm to about 1500 cm, from about 100 cm to about 1500 cm, from about 150 cm to about 1500 cm, from about 200 cm to about 1500 cm, from about 250 cm to about 1500 cm, from about 300 cm to about 1500 cm, from about 350 cm to about 1500 cm, from about 400 cm to about 1500 cm, from about 450 cm to about 1500 cm, from about 500 cm to about 1500 cm, from about 550 cm to about 1500 cm, from about 600 cm to about 1500 cm, from about 650 cm to about 1500 cm, from about 650 cm to about 1500 cm, from about 700 cm to about 1500 cm, from about 750 cm to about 1500 cm, from about 800 cm to about 1500 cm, from about 850 cm to about 1500 cm, from about 900 cm to about 1500 cm, from about 950 cm to about 1500 cm, from about 1000 cm to about 1500 cm, from about 1050 cm to about 1500 cm, from about 1100 cm to about 1500 cm, from about 1150 cm to about 1500 cm, from about 1200 cm to about 1500 cm, from about 1250 cm to about 1500 cm, from about 1300 cm to about 1500 cm, from about 1350 cm to about 1500 cm, from about 1400 cm to about 1500 cm, or from about 1450 cm to about 1500 cm. In other embodiments, L1 falls within any one of the exact numerical ranges set forth in this paragraph.

In various embodiments, one or more radius of curvature (e.g., R shown in FIG. 2) of glass substrate 232 is about 50 mm or greater. For example, R may be in a range from about 50 mm to about 10,000 mm, from about 60 mm to about 10,000 mm, from about 70 mm to about 10,000 mm, from about 80 mm to about 10,000 mm, from about 90 mm to about 10,000 mm, from about 100 mm to about 10,000 mm, from about 120 mm to about 10,000 mm, from about 140 mm to about 10,000 mm, from about 150 mm to about 10,000 mm, from about 160 mm to about 10,000 mm, from about 180 mm to about 10,000 mm, from about 200 mm to about 10,000 mm, from about 220 mm to about 10,000 mm, from about 240 mm to about 10,000 mm, from about 250 mm to about 10,000 mm, from about 260 mm to about 10,000 mm, from about 270 mm to about 10,000 mm, from about 280 mm to about 10,000 mm, from about 290 mm to about 10,000 mm, from about 300 mm to about 10,000 mm, from about 350 mm to about 10,000 mm, from about 400 mm to about 10,000 mm, from about 450 mm to about 10,000 mm, from about 500 mm to about 10,000 mm, from about 550 mm to about 10,000 mm, from about 600 mm to about 10,000 mm, from about 650 mm to about 10,000 mm, from about 700 mm to about 10,000 mm, from about 750 mm to about 10,000 mm, from about 800 mm to about 10,000 mm, from about 900 mm to about 10,000 mm, from about 950 mm to about 10,000 mm, from about 1000 mm to about 10,000 mm, from about 1250 mm to about 10,000 mm, from about 50 mm to about 1400 mm, from about 50 mm to about 1300 mm, from about 50 mm to about 1200 mm, from about 50 mm to about 1100 mm, from about 50 mm to about 1000 mm, from about 50 mm to about 950 mm, from about 50 mm to about 900 mm, from about 50 mm to about 850 mm, from about 50 mm to about 800 mm, from about 50 mm to about 750 mm, from about 50 mm to about 700 mm, from about 50 mm to about 650 mm, from about 50 mm to about 600 mm, from about 50 mm to about 550 mm, from about 50 mm to about 500 mm, from about 50 mm to about 450 mm, from about 50 mm to about 400 mm, from about 50 mm to about 350 mm, from about 50 mm to about 300 mm, or from about 50 mm to about 250 mm. In other embodiments, R falls within any one of the exact numerical ranges set forth in this paragraph.

The various embodiments of the vehicle interior system may be incorporated into vehicles such as trains, automobiles (e.g., cars, trucks, buses and the like), sea craft (boats, ships, submarines, and the like), and aircraft (e.g., drones, airplanes, jets, helicopters and the like).

### Strengthened Glass Properties

The glass substrate 232 used in the OLED display 230 may be strengthened. In one or more embodiments, glass substrate 232 may be strengthened to include compressive stress that extends from a surface to a depth of compression (DOC). The compressive stress regions are balanced by a central portion exhibiting a tensile stress. At the DOC, the stress crosses from a positive (compressive) stress to a negative (tensile) stress.

In various embodiments, glass substrate 232 may be strengthened mechanically by utilizing a mismatch of the coefficient of thermal expansion between portions of the article to create a compressive stress region and a central region exhibiting a tensile stress. In some embodiments, the glass substrate 232 may be strengthened thermally by heating the glass to a temperature above the glass transition point and then rapidly quenching.

In various embodiments, glass substrate 232 may be chemically strengthened by ion exchange. In the ion exchange process, ions at or near the surface of the glass substrate 232 are replaced by—or exchanged with—larger ions having the same valence or oxidation state. In those embodiments in which the glass substrate 232 comprises an alkali aluminosilicate glass, ions in the surface layer of the article and the larger ions are monovalent alkali metal cations, such as Li⁺, Na⁺, K⁺, Rb⁺, and Cs⁺. Alternatively, monovalent cations in the surface layer may be replaced with monovalent cations other than alkali metal cations, such as Ag⁺ or the like. In such embodiments, the monovalent ions (or cations) exchanged into the glass substrate generate a stress.

Ion exchange processes are typically carried out by immersing a glass substrate 232 in a molten salt bath (or two or more molten salt baths) containing the larger ions to be exchanged with the smaller ions in the glass substrate 232. It should be noted that aqueous salt baths may also be utilized. In addition, the composition of the bath(s) may include more than one type of larger ions (e.g., Na+ and K+) or a single larger ion. It will be appreciated by those skilled in the art that parameters for the ion exchange process, including, but not limited to, bath composition and temperature, immersion time, the number of immersions of the glass substrate 232 in a salt bath (or baths), use of multiple salt baths, additional steps such as annealing, washing, and the like, are generally determined by the composition of the glass substrate 232 (including the structure of the article and any crystalline phases present) and the desired DOC and CS of the glass substrate 232 that results from strengthening. Exemplary molten bath compositions may include nitrates, sulfates, and chlorides of the larger alkali metal ion. Typical nitrates include KNO₃, NaNO₃, LiNO₃, NaSO₄ and combinations thereof. The temperature of the molten salt bath typically is in a range from about 380° C. up to about 450° C., while immersion times range from about 15 minutes up to about 100 hours depending on glass substrate thickness, bath temperature and glass (or monovalent ion) diffusivity. However, temperatures and immersion times different from those described above may also be used.

In one or more embodiments, the glass substrates may be immersed in a molten salt bath of 100% NaNO₃, 100% KNO₃, or a combination of NaNO₃ and KNO₃ having a temperature from about 370° C. to about 480° C. In some embodiments, the glass substrate 232 may be immersed in a molten mixed salt bath including from about 5% to about 90% KNO₃ and from about 10% to about 95% NaNO₃. In one or more embodiments, the glass substrate 232 may be immersed in a second bath, after immersion in a first bath. The first and second baths may have different compositions and/or temperatures from one another. The immersion times in the first and second baths may vary. For example, immersion in the first bath may be longer than the immersion in the second bath.

In one or more embodiments, the glass substrate 232 may be immersed in a molten, mixed salt bath including NaNO₃ and KNO₃ (e.g., 49%/51%, 50%/50%, 51%/49%) having a temperature less than about 420° C. (e.g., about 400° C. or about 380° C.). for less than about 5 hours, or even about 4 hours or less.

Ion exchange conditions can be tailored to provide a “spike” or to increase the slope of the stress profile at or near the surface of the resulting glass substrate 232. The spike may result in a greater surface CS value. This spike can be achieved by a single bath or multiple baths, with the bath(s) having a single composition or mixed composition, due to the unique properties of the glass compositions used in the glass substrates described herein.

In one or more embodiments, where more than one monovalent ion is exchanged into the glass substrate, the different monovalent ions may exchange to different depths within the glass substrate 232 (and generate different magnitudes stresses within the glass substrate 232 at different depths). The resulting relative depths of the stress-generating ions can be determined and cause different characteristics of the stress profile.

CS is measured using those means known in the art, such as by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured by those methods that are known in the art, such as fiber and four point bend methods, both of which are described in ASTM standard C770-98 (2013), entitled “Standard Test Method for Measurement of Glass Stress-Optical Coefficient,” the contents of which are incorporated herein by reference in their entirety, and a bulk cylinder method. As used herein CS may be the “maximum compressive stress” which is the highest compressive stress value measured within the compressive stress layer. In some embodiments, the maximum compressive stress is located at the surface of the glass substrate 232. In other embodiments, the maximum compressive stress may occur at a depth below the surface, giving the compressive profile the appearance of a “buried peak.”

DOC may be measured by FSM or by a scattered light polariscope (SCALP) (such as the SCALP-04 scattered light polariscope available from Glasstress Ltd., located in Tallinn Estonia), depending on the strengthening method and conditions. When the glass substrate 232 is chemically strengthened by an ion exchange treatment, FSM or SCALP may be used depending on which ion is exchanged into the glass substrate 232. Where the stress in the glass substrate 232 is generated by exchanging potassium ions into the glass substrate, FSM is used to measure DOC. Where the stress is generated by exchanging sodium ions into the glass substrate 232, SCALP is used to measure DOC. Where the stress in the glass substrate 232 is generated by exchanging both potassium and sodium ions into the glass, the DOC is measured by SCALP, since it is believed the exchange depth of sodium indicates the DOC and the exchange depth of potassium ions indicates a change in the magnitude of the compressive stress (but not the change in stress from compressive to tensile); the exchange depth of potassium ions in such glass substrates is measured by FSM. Central tension or CT is the maximum tensile stress and is measured by SCALP.

In one or more embodiments, the glass substrate 232 may be strengthened to exhibit a DOC that is described as a fraction of the thickness T1 of the glass substrate 232 (as described herein). For example, in one or more embodiments, the DOC may be equal to or greater than about 0.05T1, equal to or greater than about 0.1T1, equal to or greater than about 0.11T1, equal to or greater than about 0.12T1, equal to or greater than about 0.13T1, equal to or greater than about 0.14T1, equal to or greater than about 0.15T1, equal to or greater than about 0.16T1, equal to or greater than about 0.17T1, equal to or greater than about 0.18T1, equal to or greater than about 0.19T1, equal to or greater than about 0.2T1, equal to or greater than about 0.21T1. In some embodiments, the DOC may be in a range from about 0.08T1 to about 0.25T1, from about 0.09T1 to about 0.25T1, from about 0.18T1 to about 0.25T1, from about 0.11T1 to about 0.25T1, from about 0.12T1 to about 0.25T1, from about 0.13T1 to about 0.25T1, from about 0.14T1 to about 0.25T1, from about 0.15T1 to about 0.25T1, from about 0.08T1 to about 0.24T1, from about 0.08T1 to about 0.23T1, from about 0.08T1 to about 0.22T1, from about 0.08T1 to about 0.21T1, from about 0.08T1 to about 0.2T1, from about 0.08T1 to about 0.19T1, from about 0.08T1 to about 0.18T1, from about 0.08T1 to about 0.17T1, from about 0.08T1 to about 0.16T1, or from about 0.08T1 to about 0.15T1. In some instances, the DOC may be about 20 μm or less. In one or more embodiments, the DOC may be about 40 μm or greater (e.g., from about 40 μm to about 300 μm, from about 50 μm to about 300 μm, from about 60 μm to about 300 μm, from about 70 μm to about 300 μm, from about 80 μm to about 300 μm, from about 90 μm to about 300 μm, from about 100 μm to about 300 μm, from about 110 μm to about 300 μm, from about 120 μm to about 300 μm, from about 140 μm to about 300 μm, from about 150 μm to about 300 μm, from about 40 μm to about 290 μm, from about 40 μm to about 280 μm, from about 40 μm to about 260 μm, from about 40 μm to about 250 μm, from about 40 μm to about 240 μm, from about 40 μm to about 230 μm, from about 40 μm to about 220 μm, from about 40 μm to about 210 μm, from about 40 μm to about 200 μm, from about 40 μm to about 180 μm, from about 40 μm to about 160 μm, from about 40 μm to about 150 μm, from about 40 μm to about 140 μm, from about 40 μm to about 130 μm, from about 40 μm to about 120 μm, from about 40 μm to about 110 μm, or from about 40 μm to about 100 μm. In other embodiments, DOC falls within any one of the exact numerical ranges set forth in this paragraph.

In one or more embodiments, the strengthened glass substrate 232 may have a CS (which may be found at the surface or a depth within the glass substrate 232) of about 200 MPa or greater, 300 MPa or greater, 400 MPa or greater, about 500 MPa or greater, about 600 MPa or greater, about 700 MPa or greater, about 800 MPa or greater, about 900 MPa or greater, about 930 MPa or greater, about 1000 MPa or greater, or about 1050 MPa or greater.

In one or more embodiments, the strengthened glass substrate 232 may have a maximum tensile stress or central tension (CT) of about 20 MPa or greater, about 30 MPa or greater, about 40 MPa or greater, about 45 MPa or greater, about 50 MPa or greater, about 60 MPa or greater, about 70 MPa or greater, about 75 MPa or greater, about 80 MPa or greater, or about 85 MPa or greater. In some embodiments, the maximum tensile stress or central tension (CT) may be in a range from about 40 MPa to about 100 MPa. In other embodiments, CS falls within the exact numerical ranges set forth in this paragraph.

### Glass Compositions

Suitable glass compositions for use in glass substrate 232 include soda lime glass, aluminosilicate glass, borosilicate glass, boroaluminosilicate glass, alkali-containing aluminosilicate glass, alkali-containing borosilicate glass, and alkali-containing boroaluminosilicate glass.

Unless otherwise specified, the glass compositions disclosed herein are described in mole percent (mol %) as analyzed on an oxide basis.

In one or more embodiments, the glass composition may include SiO₂ in an amount in a range from about 66 mol % to about 80 mol %, from about 67 mol % to about 80 mol %, from about 68 mol % to about 80 mol %, from about 69 mol % to about 80 mol %, from about 70 mol % to about 80 mol %, from about 72 mol % to about 80 mol %, from about 65 mol % to about 78 mol %, from about 65 mol % to about 76 mol %, from about 65 mol % to about 75 mol %, from about 65 mol % to about 74 mol %, from about 65 mol % to about 72 mol %, or from about 65 mol % to about 70 mol %, and all ranges and sub-ranges therebetween.

In one or more embodiments, the glass composition includes Al₂O₃ in an amount greater than about 4 mol %, or greater than about 5 mol %. In one or more embodiments, the glass composition includes Al₂O₃ in a range from greater than about 7 mol % to about 15 mol %, from greater than about 7 mol % to about 14 mol %, from about 7 mol % to about 13 mol %, from about 4 mol % to about 12 mol %, from about 7 mol % to about 11 mol %, from about 8 mol % to about 15 mol %, from about 9 mol % to about 15 mol %, from about 10 mol % to about 15 mol %, from about 11 mol % to about 15 mol %, or from about 12 mol % to about 15 mol %, and all ranges and sub-ranges therebetween. In one or more embodiments, the upper limit of Al₂O₃ may be about 14 mol %, 14.2 mol %, 14.4 mol %, 14.6 mol %, or 14.8 mol %.

In one or more embodiments, the glass article is described as an aluminosilicate glass article or including an aluminosilicate glass composition. In such embodiments, the glass composition or article formed therefrom includes SiO₂ and Al₂O₃ and is nota soda lime silicate glass. In this regard, the glass composition or article formed therefrom includes Al₂O₃ in an amount of about 2 mol % or greater, 2.25 mol % or greater, 2.5 mol % or greater, about 2.75 mol % or greater, about 3 mol % or greater.

In one or more embodiments, the glass composition comprises B₂O₃ (e.g., about 0.01 mol % or greater). In one or more embodiments, the glass composition comprises B₂O₃ in an amount in a range from about 0 mol % to about 5 mol %, from about 0 mol % to about 4 mol %, from about 0 mol % to about 3 mol %, from about 0 mol % to about 2 mol %, from about 0 mol % to about 1 mol %, from about 0 mol % to about 0.5 mol %, from about 0.1 mol % to about 5 mol %, from about 0.1 mol % to about 4 mol %, from about 0.1 mol % to about 3 mol %, from about 0.1 mol % to about 2 mol %, from about 0.1 mol % to about 1 mol %, from about 0.1 mol % to about 0.5 mol %, and all ranges and sub-ranges therebetween. In one or more embodiments, the glass composition is substantially free of B₂₀₃.

As used herein, the phrase “substantially free” with respect to the components of the composition means that the component is not actively or intentionally added to the composition during initial batching, but may be present as an impurity in an amount less than about 0.001 mol %.

In one or more embodiments, the glass composition optionally comprises P₂O₅ (e.g, about 0.01 mol % or greater). In one or more embodiments, the glass composition comprises a non-zero amount of P₂O₅ up to and including 2 mol %, 1.5 mol %, 1 mol %, or 0.5 mol %. In one or more embodiments, the glass composition is substantially free of P₂O₅.

In one or more embodiments, the glass composition may include a total amount of R₂O (which is the total amount of alkali metal oxide such as Li₂O, Na₂O, K₂O, Rb₂O, and Cs₂O) that is greater than or equal to about 8 mol %, greater than or equal to about 10 mol %, or greater than or equal to about 12 mol %. In some embodiments, the glass composition includes a total amount of R₂O in a range from about 8 mol % to about 20 mol %, from about 8 mol % to about 18 mol %, from about 8 mol % to about 16 mol %, from about 8 mol % to about 14 mol %, from about 8 mol % to about 12 mol %, from about 9 mol % to about 20 mol %, from about 10 mol % to about 20 mol %, from about 11 mol % to about 20 mol %, from about 12 mol % to about 20 mol %, from about 13 mol % to about 20 mol %, from about 10 mol % to about 14 mol %, or from 11 mol % to about 13 mol %, and all ranges and sub-ranges therebetween. In one or more embodiments, the glass composition may be substantially free of Rb₂O, Cs₂O or both Rb₂O and Cs₂O. In one or more embodiments, the R₂O may include the total amount of Li₂O, Na₂O and K₂O only. In one or more embodiments, the glass composition may comprise at least one alkali metal oxide selected from Li₂O, Na₂O and K₂O, wherein the alkali metal oxide is present in an amount greater than about 8 mol % or greater.

In one or more embodiments, the glass composition comprises Na₂O in an amount greater than or equal to about 8 mol %, greater than or equal to about 10 mol %, or greater than or equal to about 12 mol %. In one or more embodiments, the composition includes Na₂O in a range from about from about 8 mol % to about 20 mol %, from about 8 mol % to about 18 mol %, from about 8 mol % to about 16 mol %, from about 8 mol % to about 14 mol %, from about 8 mol % to about 12 mol %, from about 9 mol % to about 20 mol %, from about 10 mol % to about 20 mol %, from about 11 mol % to about 20 mol %, from about 12 mol % to about 20 mol %, from about 13 mol % to about 20 mol %, from about 10 mol % to about 14 mol %, or from 11 mol % to about 16 mol %, and all ranges and sub-ranges therebetween.

In one or more embodiments, the glass composition includes less than about 4 mol % K₂O, less than about 3 mol % K₂O, or less than about 1 mol % K₂O. In some instances, the glass composition may include K₂O in an amount in a range from about 0 mol % to about 4 mol %, from about 0 mol % to about 3.5 mol %, from about 0 mol % to about 3 mol %, from about 0 mol % to about 2.5 mol %, from about 0 mol % to about 2 mol %, from about 0 mol % to about 1.5 mol %, from about 0 mol % to about 1 mol %, from about 0 mol % to about 0.5 mol %, from about 0 mol % to about 0.2 mol %, from about 0 mol % to about 0.1 mol %, from about 0.5 mol % to about 4 mol %, from about 0.5 mol % to about 3.5 mol %, from about 0.5 mol % to about 3 mol %, from about 0.5 mol % to about 2.5 mol %, from about 0.5 mol % to about 2 mol %, from about 0.5 mol % to about 1.5 mol %, or from about 0.5 mol % to about 1 mol %, and all ranges and sub-ranges therebetween. In one or more embodiments, the glass composition may be substantially free of K₂O.

In one or more embodiments, the glass composition is substantially free of Li₂O.

In one or more embodiments, the amount of Na₂O in the composition may be greater than the amount of Li₂O. In some instances, the amount of Na₂O may be greater than the combined amount of Li₂O and K₂O. In one or more alternative embodiments, the amount of Li₂O in the composition may be greater than the amount of Na₂O or the combined amount of Na₂O and K₂O.

In one or more embodiments, the glass composition may include a total amount of RO (which is the total amount of alkaline earth metal oxide such as CaO, MgO, BaO, ZnO and SrO) in a range from about 0 mol % to about 2 mol %. In some embodiments, the glass composition includes a non-zero amount of RO up to about 2 mol %. In one or more embodiments, the glass composition comprises RO in an amount from about 0 mol % to about 1.8 mol %, from about 0 mol % to about 1.6 mol %, from about 0 mol % to about 1.5 mol %, from about 0 mol % to about 1.4 mol %, from about 0 mol % to about 1.2 mol %, from about 0 mol % to about 1 mol %, from about 0 mol % to about 0.8 mol %, from about 0 mol % to about 0.5 mol %, and all ranges and sub-ranges therebetween.

In one or more embodiments, the glass composition includes CaO in an amount less than about 1 mol %, less than about 0.8 mol %, or less than about 0.5 mol %. In one or more embodiments, the glass composition is substantially free of CaO.

In some embodiments, the glass composition comprises MgO in an amount from about 0 mol % to about 7 mol %, from about 0 mol % to about 6 mol %, from about 0 mol % to about 5 mol %, from about 0 mol % to about 4 mol %, from about 0.1 mol % to about 7 mol %, from about 0.1 mol % to about 6 mol %, from about 0.1 mol % to about 5 mol %, from about 0.1 mol % to about 4 mol %, from about 1 mol % to about 7 mol %, from about 2 mol % to about 6 mol %, or from about 3 mol % to about 6 mol %, and all ranges and sub-ranges therebetween.

In one or more embodiments, the glass composition comprises ZrO₂ in an amount equal to or less than about 0.2 mol %, less than about 0.18 mol %, less than about 0.16 mol %, less than about 0.15 mol %, less than about 0.14 mol %, less than about 0.12 mol %. In one or more embodiments, the glass composition comprises ZrO₂ in a range from about 0.01 mol % to about 0.2 mol %, from about 0.01 mol % to about 0.18 mol %, from about 0.01 mol % to about 0.16 mol %, from about 0.01 mol % to about 0.15 mol %, from about 0.01 mol % to about 0.14 mol %, from about 0.01 mol % to about 0.12 mol %, or from about 0.01 mol % to about 0.10 mol %, and all ranges and sub-ranges therebetween.

In one or more embodiments, the glass composition comprises SnO₂ in an amount equal to or less than about 0.2 mol %, less than about 0.18 mol %, less than about 0.16 mol %, less than about 0.15 mol %, less than about 0.14 mol %, less than about 0.12 mol %. In one or more embodiments, the glass composition comprises SnO₂ in a range from about 0.01 mol % to about 0.2 mol %, from about 0.01 mol % to about 0.18 mol %, from about 0.01 mol % to about 0.16 mol %, from about 0.01 mol % to about 0.15 mol %, from about 0.01 mol % to about 0.14 mol %, from about 0.01 mol % to about 0.12 mol %, or from about 0.01 mol % to about 0.10 mol %, and all ranges and sub-ranges therebetween.

In one or more embodiments, the glass composition may include an oxide that imparts a color or tint to the glass articles. In some embodiments, the glass composition includes an oxide that prevents discoloration of the glass article when the glass article is exposed to ultraviolet radiation. Examples of such oxides include, without limitation oxides of: Ti, V, Cr, Mn, Fe, Co, Ni, Cu, Ce, W, and Mo.

In one or more embodiments, the glass composition includes Fe expressed as Fe₂O₃, wherein Fe is present in an amount up to (and including) about 1 mol %. In some embodiments, the glass composition is substantially free of Fe. In one or more embodiments, the glass composition comprises Fe₂O₃ in an amount equal to or less than about 0.2 mol %, less than about 0.18 mol %, less than about 0.16 mol %, less than about 0.15 mol %, less than about 0.14 mol %, less than about 0.12 mol %. In one or more embodiments, the glass composition comprises Fe₂O₃ in a range from about 0.01 mol % to about 0.2 mol %, from about 0.01 mol % to about 0.18 mol %, from about 0.01 mol % to about 0.16 mol %, from about 0.01 mol % to about 0.15 mol %, from about 0.01 mol % to about 0.14 mol %, from about 0.01 mol % to about 0.12 mol %, or from about 0.01 mol % to about 0.10 mol %, and all ranges and sub-ranges therebetween.

Where the glass composition includes TiO₂, TiO₂ may be present in an amount of about 5 mol % or less, about 2.5 mol % or less, about 2 mol % or less or about 1 mol % or less. In one or more embodiments, the glass composition may be substantially free of TiO₂.

An exemplary glass composition includes SiO₂ in an amount in a range from about 65 mol % to about 75 mol %, Al₂O₃ in an amount in a range from about 8 mol % to about 14 mol %, Na₂O in an amount in a range from about 12 mol % to about 17 mol %, K₂O in an amount in a range of about 0 mol % to about 0.2 mol %, and MgO in an amount in a range from about 1.5 mol % to about 6 mol %. Optionally, SnO₂ may be included in the amounts otherwise disclosed herein. It should be understood, that while the preceding glass composition paragraphs express approximate ranges, in other embodiments, glass substrate 232 may be made from any glass composition without falling with any one of the exact numerical ranges discussed above.

### Examples

Embodiments of the present disclosure may be understood more completely via the following examples.

In the following examples, finite element analysis was performed on a three-layer OLED display stack including a 1.1 mm thick sheet of Corning AutoGrade™ glass as a glass substrate and an OLED display module simulated as a 1 mm thick layer of PET (for purposes of the simulation, the entire OLED display module was simulated as a uniform PET sheet). The glass substrate and the OLED display module were adhered to one another by a layer of OCA with varying characteristics to illustrate the effects of the adhesive. The simulations demonstrate the strain distributions resulting from cold-forming the stack to a radius of curvature (e.g., corresponding to R depicted in FIG. 2) of 170 mm along a direction of the length of each of the samples.

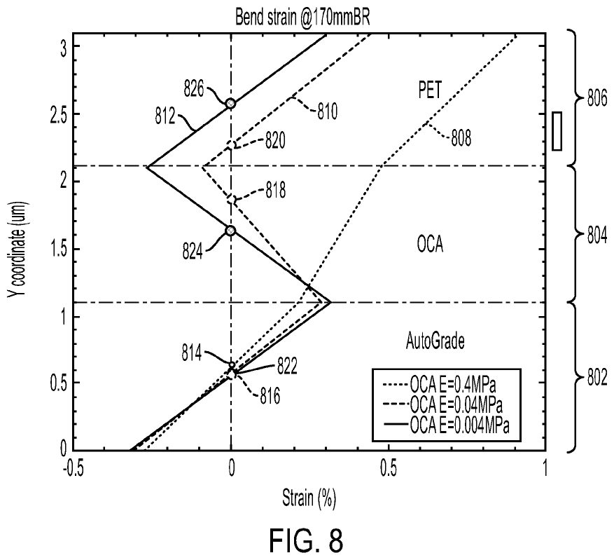

In a first set of examples, a 1.1 mm thick sheet of Corning AutoGrade™ glass (having a Young's modulus of 76.7 GPa and a Poisson's ratio of 0.21) adhered to a 1.0 mm thick PET layer by a 1 mm thick OCA layer was simulated. Each of the layers had a length of 644.9 mm and a width of 146.5 mm. The Young's modulus of the OCA layer was varied from 0.4 MPa, to 0.04 MPa, to 0.004 MPa to generate three simulations investigating the effect of OCA modulus on neutral plane decoupling. The results are depicted in FIG. 8. FIG. 8 plots a simulated distribution of bending strain as a function of depth (labelled as “Y coordinate”) within the OLED display, with zero depth corresponding to a first surface (e.g., corresponding to the first major surface 234 of the glass substrate 232 described herein with respect to FIG. 2). As such, in FIG. 8, a first depth interval 802 corresponds to the glass substrate, a second depth interval 804 corresponds to the OCA layer, and a third depth interval 806 corresponds to the PET layer. A first strain distribution 808 represents the simulated strain distribution when the OCA layer included a Young's modulus of 0.4 MPa. A second strain distribution 810 represents the simulated strain distribution when the OCA layer included a Young's modulus of 0.04 MPa. A third strain distribution 812 represents the simulated strain distribution when the OCA layer included a Young's modulus of 0.004 MPa.

As shown in FIG. 8, the strain distribution 808 included a single neutral plane 814 lying within the central 40% of the glass substrate. That is, an adhesive modulus of 0.4 MPa did not decouple the layers in the display stack such that the PET layer is simulated to be under a peak strain of about 0.9% from the cold-forming. Such strain may render display modules instable and render the display unreliable and prone to failure (e.g., cracking, delamination, etc.). The strain distribution 810, in contrast to the strain distribution 808, included three neutral planes 816, 818, and 820, each contained in one of the layers of the simulated display stack. As such, an OCA modulus of 0.04 MPa decoupled the bending-induced strain distributions in each of the layers. As a result, the PET layer was simulated to be under a peak strain of about 0.45% from the cold-forming, representing a 50% reduction from the strain distribution 808. Such a strain reduction beneficially reduces the probability of display failure from cold-forming induced strains, thereby increasing the reliability of the display. In embodiments, the OLED display modules described herein are under a maximum bending strain that is less than or equal to 0.5%.

The third strain distribution 812 included three neutral planes 822, 824, and 826, with each of the three neutral planes 822, 824, and 826 being contained in one of the layers of simulated display stack. As compared to the second strain distribution 810, in the third strain distribution 812, the neutral planes 822, 824, and 826 are disposed more proximate to the centers of the thicknesses of each layer of the simulated display stack. That is, the relatively low Young's modulus of 0.004 MPa in the OCA layer resulted in nearly perfect decoupling of the bending strain distributions in each layer. As a result, the PET layer was simulated to be under a peak strain of about 0.3%, representing a 66% reduction from the strain distribution 808. From the preceding analysis, it can be seen that that a Young's modulus of the OCA layer may be selected to decouple the bending strain distributions in each of the layers to lower the peak strain. In this example, the OCA layer may include a Young's modulus that is less than 0.000136 times the Young's modulus of an adjacent functional layer of an OLED display module to provide sufficient decoupling for neutral plane separation, when a thickness of the OCA layer is less than or equal to a thickness of the adjacent functional layer.

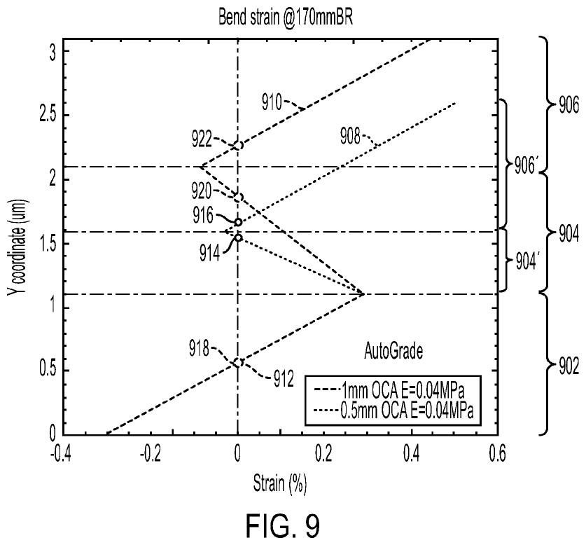

In a second set of examples, a 1.1 mm thick sheet of Corning AutoGrade™ glass (having a Young's modulus of 76.7 GPa and a Poisson's ratio of 0.21) adhered to a 1.0 mm thick PET layer by an OCA layer was simulated as a display stack. Each of the layers had a length of 644.9 mm and a width of 146.5 mm. The Young's modulus of the OCA layer was 0.04 MPa, and the thickness of the OCA layer was varied between 1 mm and 0.5 mm to generate simulations investigating the effect of OCA layer thickness on neutral plane decoupling. The results are depicted in FIG. 9. FIG. 9 plots a simulated distribution of bending strain as a function of depth (labelled as “Y coordinate”) within the simulated display stack, with zero depth corresponding to a first surface (e.g., corresponding to the first major surface 234 of the glass substrate 232 described herein with respect to FIG. 2). As such, in FIG. 9, a first depth interval 902 corresponds to the glass substrate, a second depth interval 904 (904′ for the sample with a 0.5 mm thick OCA layer) corresponds to the OCA layer, and a third depth interval 906 corresponds to the PET layer (906′ for the sample with a 0.5 mm thick OCA layer). A first strain distribution 908 represents the simulated strain distribution when the OCA layer included thickness of 0.5 mm. A second strain distribution 910 represents the simulated strain distribution when the OCA layer included a thickness of 1 mm.

As shown in FIG. 9, both strain distributions 908 and 910 resulted in decoupling of the bending strain distributions of the simulated display stacks. The strain distribution 908 included three neutral planes 912, 914, and 916, with each of the neutral planes being located in one of the layers of the simulated display stack. The strain distribution 910 included three neutral planes 918, 920, and 922, with each of the neutral planes being located in one of the layers of the simulated display stack. As shown, however, the strain distribution, associated with the thicker OCA layer, more closely approximately perfect decoupling, with the neutral planes 918, 920, and 922 lying more proximate to thickness centers of each layer of the display stack. As a result, the 1 mm thick OCA layer resulted in the PET layer being under a peak strain of about 0.45%, about a 10% reduction over the case of the case with the 0.5 mm OCA layer. The preceding example demonstrates that thicker adhesive layers result in better decoupling and reduced peak strains.

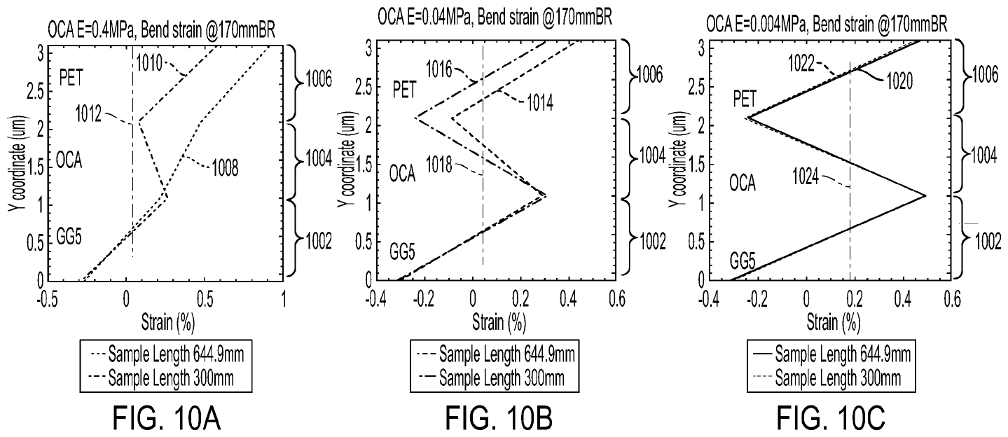

In a third set of examples, a 1.1 mm thick sheet of Corning AutoGrade™ glass (having a Young's modulus of 76.7 GPa and a Poisson's ratio of 0.21) adhered to a 1.0 mm thick PET layer by a 1.0 mm thick OCA layer was simulated as a display stack. The dimensions of the samples were varied to analyze the effect of sample size on bending strain decoupling Simulations were performed with the OCA layer having Young's moduli of 0.4 MPa, 0.04 MPa, and 0.004 MPa, respectively. Two simulations were performed at each modulus, a first where of the layers had a length of 644.9 mm and a width of 146.5 mm; and a second where each of the layers had a length of 300 mm and a width of 100 mm. The results are depicted in FIGS. 10A-10C. FIG. 10A depicts the results where the OCA layer had a Young's modulus of 0.4 MPa. FIG. 10B depicts the results where the OCA layer had a Young's modulus of 0.04 MPa. FIG. 10C depicts the results where the OCA layer had a Young's modulus of 0.004 MPa.

FIGS. 10A, 10B, and 10C depict plots of simulated distributions of bending strain as a function of depth (labelled as “Y coordinate”) within the simulated display stack, with zero depth corresponding to a first surface (e.g., corresponding to the first major surface 234 of the glass substrate 232 described herein with respect to FIG. 2). As such, in FIGS. 10A-10C, a first depth interval 1002 corresponds to the glass substrate, a second depth interval 1004 corresponds to the OCA layer, and a third depth interval 1006 corresponds to the PET layer. FIG. 10A depicts a first bending strain distribution 1008 associated with the longer sample length and a second bending strain distribution 1010 associated with the shorter sample length. In both samples, the OCA layer had a Young's modulus of 0.4 MPa. As shown, both the first and second bending strain distributions 1008 and 1010 only include a single neutral plane (where they cross a zero strain axis 1012) lying in the glass substrate, with the second bending strain distribution 1010 having a lower peak strain in the PTE layer.

FIG. 10B depicts a first bending strain distribution 1014 associated with the longer sample length and a second bending strain distribution 1016 associated with the shorter sample length. In both samples, the OCA layer had a Young's modulus of 0.04 MPa. As shown, both the first and second bending strain distributions 1014 and 1016 include three neutral planes (where each of the first and second bending strain distributions 1014 and 1016 intersect a zero-strain axis 1018). As shown, the second bending strain distribution 1016, associated with the shorter sample length, more closely approximates perfect decoupling, where each neutral plane lies closer to a center of each layer and, as a result, exhibits lower peak strain in the PET layer. FIG. 10C depicts a first bending strain distribution 1020 associated with the longer sample length and a second bending strain distribution 1022 associated with the shorter sample length. In both samples, the OCA layer had a Young's modulus of 0.004 MPa. As shown, both the first and second bending strain distributions 1020 and 1022 include three neutral planes (where each of the first and second bending strain distributions 1020 and 1022 intersect a zero-strain axis 1024. As shown, the second bending strain distribution 1022, associated with the shorter sample length, more closely approximates perfect decoupling, where each neutral plane lies closer to a center of each layer and, as a results, exhibits lower peak strain in the PET layer.

As can be deduced from FIGS. 10A-10C, the dimensionality along which the sample is curved (the length in the examples described with respect to FIGS. 10A-10C) effects the extent to which the bending strain distributions in each layer of the display stack are decoupled from one another. The effect of sample dimension appears to be more pronounced with increasing adhesive Young's modulus, as the difference in peak strain on the PET is greatest in the example depicted in FIG. 10A. However, irrespective of the particular adhesive layer used, shorter sample sizes (e.g., smaller displays) along the direction of curvature may promote neutral plane separation while using higher modulus adhesives, which may beneficially improve the strength of the OLED display assembly against certain impact events.

A first aspect of the present disclosure includes display device for a vehicle interior system, the display device comprising: a glass substrate comprising a first major surface and second major surface opposite the first major surface, wherein the glass substrate comprises a length extending in a first direction that is greater than or equal to 200 mm; an organic light emitting diode (OLED) display module disposed on the second major surface, the OLED display module comprising a plurality of functional layers; a support structure mechanically coupled to the glass substrate and the OLED display module to retain the glass substrate and the OLED display module in a curved configuration; and a plurality of adhesive layers comprising an attachment adhesive layer attaching the OLED display module to the second major surface and a plurality of layers of display adhesive attaching the plurality of functional layers to one another, wherein: the plurality of adhesive layers comprises n adhesive layers, and each of the plurality of adhesive layers comprises a Young's modulus that is less than or equal 1.5 MPa to decouple strain distributions in the glass substrate and the plurality of functional layers from one another.

A second aspect of the present disclosure includes a display device according to the first aspect, wherein, as a result of the support structure retaining the glass substrate and the OLED display module in the curved configuration, the display device comprises m=2n+1 neutral planes, each neutral plane representing a surface of zero bending strain.

A third aspect of the present disclosure includes a display device according to any of the first through the second aspects, wherein the OLED display module covers at least 50% of a surface area of the second major surface.

A fourth aspect of the present disclosure includes a display device according to any of the first through the third aspects, wherein the support structure retains the glass substrate and the OLED display module such that entireties of the glass substrate and the OLED display modules are curved along the first direction.

A fifth aspect of the present disclosure includes a display device according to any of the first through the fourth aspects, wherein the glass substrate and the OLED display module comprise radii of curvature that are greater than or equal to 100 mm.

A sixth aspect of the present disclosure includes a display device according to any of the first through the fifth aspects, wherein each of the plurality of adhesive layers comprises a Young's modulus and thickness that is selected based at least in part on a Young's modulus and thickness of adjacent portions of the display device to separate the neutral planes within the adjacent portions.

A seventh aspect of the present disclosure includes a display device according to any of the first through the sixth aspects, wherein each of the plurality of adhesive layers comprises a Young's modulus that is less than or equal to one hundredth of the young moduli of adjacent portions

An eighth aspect of the present disclosure includes a display device according to any of the first through the seventh aspects, wherein each of the plurality of adhesive layers comprises a Young's modulus that is less than or equal to 0.5 MPa.

A ninth aspect of the present disclosure includes a display device according to any of the first through the eighth aspects, wherein the plurality of functional layers of the OLED display module comprise Young's moduli that are less than or equal to 10 GPa.

A tenth aspect of the present disclosure includes a display device according to any of the first through the ninth aspects, wherein each of the plurality of adhesive layers comprises an optically clear adhesive and/or a pressure sensitive adhesive.

An eleventh aspect of the present disclosure includes a display device according to any of the first through the tenth aspects, wherein the plurality of adhesive layers comprise one or more of a silicone-based polymer, an acrylate-based polymer, an epoxy-based polymer, a thiol-containing polymer, a polyimide-based material, or a polyurethane.

A twelfth aspect of the present disclosure includes a display device according to any of the first through the eleventh aspects, wherein the first major surface and the second major surface define a thickness of the glass substrate that is greater than or equal to 0.3 mm and less than or equal to 2 mm.

A thirteenth aspect of the present disclosure includes a display device according to any of the first through the twelfth aspects, wherein the glass substrate comprises a Young's modulus of greater than or equal to 60 GPa and less than or equal to 80 GPa.

A fourteenth aspect of the present disclosure includes a display device according to any of the first through the thirteenth aspects, wherein a first functional layer of the plurality of functional layers is disposed adjacent to the attachment adhesive layer and comprises a Young's modulus of less than or equal to 6 GPa and a thickness of less than or equal to 1 mm.

A fifteenth aspect of the present disclosure includes a display device according to any of the first through the fourteenth aspects, wherein the attachment adhesive layer comprises a thickness of greater than or equal to 0.5 mm and a Young's modulus of less than or equal to 0.4 MPa.

A sixteenth aspect of the present disclosure includes a display device according to any of the first through the fifteenth aspects, wherein both the glass substrate and the OLED display module are cold-formed into the curved configuration.

A seventeenth aspect of the present disclosure includes a display device according to any of the first through the sixteenth aspects, wherein each one of the plurality of neutral planes is contained in one of the plurality of functional layers, one of the plurality of adhesive layers, or the glass substrate such that each of the plurality of functional layers, the plurality of adhesive layers, and the glass substrate contains one of the m neutral planes.

An eighteenth aspect of the present disclosure includes a display device according to any of the first through the seventeenth aspects, wherein each one of the plurality of neutral planes is disposed in a central 20% of a thickness of one of the plurality of functional layers, one of the plurality of adhesive layer, or the glass substrate.

A nineteenth aspect of the present disclosure includes a vehicle interior system comprising: a glass substrate comprising a first major surface and a second major surface opposite the first major surface, wherein the glass substrate comprises a length extending in a first direction that is greater than or equal to 200 mm and a width extending in a second direction perpendicular to the first direction that is greater than or equal to 100 mm; a support structure mechanically coupled to the glass substrate and retaining the glass substrate in a curved configuration such that at least a portion of the glass substrate is curved along at least one of the first direction and the second direction; an organic light emitting diode (OLED) display module attached to the second major surface via an attachment adhesive layer disposed directly on the second major surface, wherein: the OLED display module is retained in the curved configuration via the attachment adhesive layer such that different portions of the OLED display module are placed in tension and compression, the OLED display module comprises a plurality of functional layers attached to one another via a plurality of layers of display adhesive disposed between successive ones of the plurality of functional layers, and the plurality of layers of display adhesive each comprise a Young's modulus and thickness selected such that the compression and tension placed on the different portions of the OLED display module results in each of the plurality of functional layers and each of the plurality of layers of display adhesive containing a separate neutral plane.

A twentieth aspect includes a vehicle interior system according to the nineteenth aspect, wherein the OLED display module covers at least 50% of a surface area of the second major surface.

A twenty first aspect includes a vehicle interior system according to any of the nineteenth through the twentieth aspects, wherein the support structure retains the glass substrate and the OLED display module such that entireties of the glass substrate and the OLED display modules are curved in the first direction.

A twenty second aspect includes a vehicle interior system according to any of the nineteenth through the twenty first aspects, wherein the glass substrate and the OLED display module comprise radii of curvature that are greater than or equal to 100 mm.

A twenty third aspect includes a vehicle interior system according to any of the nineteenth through the twenty second aspects, wherein the layer of attachment adhesive and the plurality of layers of display adhesive each comprise a Young's modulus that is less than or equal to one hundredth of the young moduli of adjacent portions

A twenty fourth aspect includes a vehicle interior system according to any of the nineteenth through the twenty third aspects, wherein the layer of attachment adhesive and the plurality of layers of display adhesive each comprise a Young's modulus that is less than or equal to 1.5 MPa.

A twenty fifth aspect includes a vehicle interior system according to any of the nineteenth through the twenty fourth aspects, wherein the plurality of functional layers of the OLED display module comprise Young's moduli that are less than or equal to 10 GPa.

A twenty sixth aspect includes a vehicle interior system according to any of the nineteenth through the twenty fifth aspects, wherein the attachment adhesive layer and the plurality of layers of display adhesive each comprise an optically clear adhesive and/or a pressure sensitive adhesive.

A twenty seventh aspect includes a vehicle interior system according to any of the nineteenth through the twenty sixth aspects, wherein the first major surface and the second major surface define a thickness of the glass substrate that is greater than or equal to 0.3 mm and less than or equal to 2 mm.

A twenty eighth aspect includes a vehicle interior system according to any of the nineteenth through the twenty seventh aspects, wherein the glass substrate comprises a chemically strengthened glass with a Young's modulus of greater than or equal to 60 GPa and less than or equal to 80 GPa.

A twenty ninth aspect includes a vehicle interior system according to any of the nineteenth through the twenty second aspects, wherein a first functional layer of the plurality of functional layers is disposed adjacent to the attachment adhesive layer and comprises a Young's modulus of less than or equal to 6 GPa and a thickness of less than or equal to 1 mm.

A thirtieth aspect includes a vehicle interior system according to any of the nineteenth through the twenty ninth aspects, wherein the attachment adhesive layer comprises a thickness of greater than or equal to 0.5 mm and a Young's modulus of greater than or equal to 0.04 MPa and less than or equal to 0.4 MPa.

A thirty first aspect of the present disclosure includes a method of manufacturing a display device comprising: attaching an organic light emitting diode (OLED) display module to a glass substrate via an attachment adhesive layer, wherein the glass substrate comprises a first major surface and a second major surface opposing the first major surface and a length in a first direction that is greater than or equal to 200 mm, wherein the OLED display module comprises a plurality of functional layers attached to one another via a plurality of layers of display adhesive and wherein the OLED display module comprises a planar shape prior to being attached to the glass substrate; and bending the OLED display module into a curved configuration that corresponds to the glass substrate, wherein the bending of the OLED display module results in each of the plurality of functional layers and the plurality of layers of display adhesive comprising a separate neutral plane representing a surface of zero bending strain.

A thirty second aspect includes a method according to the thirty first aspect, further comprising cold-forming the glass substrate into the curved configuration.

A thirty third aspect includes a method according to any of the thirty first through the thirty second aspects, wherein the cold-forming the glass substrate into the curved configuration comprises attaching the glass substrate to a support structure that retains the glass substrate in the curved configuration.

A thirty fourth aspect includes a method according to any of the thirty first through the thirty third aspects, wherein the bending of the OLED display module occurs during the cold-forming of the glass substrate.

A thirty fifth aspect includes a method according to any of the thirty first through the thirty fourth aspects, wherein the bending of the OLED display module occurs after the cold-forming of the glass substrate.

A thirty sixth aspect includes a method according to any of the thirty first through the thirty fifth aspects, wherein the adhesive attachment layer comprises a thickness and a Young's modulus that is selected based on thicknesses and Young's moduli of the glass substrate and a first functional layer of the plurality of functional layers disposed adjacent to the glass attachment adhesive layer such that the glass substrate and the attachment adhesive layer each contain a separate neutral plane.

A thirty seventh aspect includes a method according to any of the thirty first through the thirty sixth aspects, wherein each of the plurality of layers of display adhesive comprises an optically clear adhesive and/or a pressure sensitive adhesive.

A thirty eighth aspect includes a method according to any of the thirty first through the thirty seventh aspects, wherein the plurality of layers of display adhesive comprise one or more of a silicone-based polymer, an acrylate-based polymer, an epoxy-based polymer, a thiol-containing polymer, a polyimide-based material, or a polyurethane.

A thirty ninth aspect includes a method according to any of the thirty first through the thirty eighth aspects, wherein the glass substrate comprises a chemically strengthened glass with a Young's modulus of greater than or equal to 60 GPa and less than or equal to 80 GPa.

A fortieth aspect includes a method according to any of the thirty first through the thirty ninth aspects, wherein a first functional layer of the plurality of functional layers is disposed adjacent to the glass substrate and comprises a Young's modulus of less than or equal to 6 GPa and a thickness of less than or equal to 1 mm.

A forty first aspect includes a method according to any of the thirty first through the fortieth aspects, wherein the attachment adhesive layer comprises a thickness of greater than or equal to 0.5 mm and a Young's modulus of less than or equal to 0.4 MPa.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

1. A display device for a vehicle interior system, the display device comprising:
a glass substrate comprising a first major surface and second major surface opposite the first major surface, wherein the glass substrate comprises a length extending in a first direction that is greater than or equal to 200 mm;
an organic light emitting diode (OLED) display module disposed on the second major surface, the OLED display module comprising a plurality of functional layers;
a support structure mechanically coupled to the glass substrate and the OLED display module to retain the glass substrate and the OLED display module in a curved configuration; and
a plurality of adhesive layers comprising an attachment adhesive layer attaching the OLED display module to the second major surface and a plurality of layers of display adhesive attaching the plurality of functional layers to one another, wherein:
the plurality of adhesive layers comprises n adhesive layers, and
each of the plurality of adhesive layers comprises a Young's modulus that is less than or equal 1.5 MPa to decouple strain distributions in the glass substrate and the plurality of functional layers from one another, wherein, as a result of the support structure retaining the glass substrate and the OLED display module in the curved configuration, the display device comprises m=2n+1 neutral planes, each neutral plane representing a surface of zero bending strain.

2. (canceled)

3. The display device of claim 1, wherein the OLED display module covers at least 50% of a surface area of the second major surface.

4. The display device of claim 1, wherein the entireties of the glass substrate and the OLED display module are curved along the first direction.

5. The display device of claim 1, wherein the glass substrate and the OLED display module comprise radii of curvature that are greater than or equal to 100 mm.

6. The display device of claim 1, wherein each of the plurality of adhesive layers comprises a Young's modulus and thickness that is selected based at least in part on a Young's modulus and thickness of adjacent portions of the display device to separate the neutral planes within the adjacent portions.

7. The display device of claim 1, wherein each of the plurality of adhesive layers comprises a Young's modulus that is less than or equal to one hundredth of the young moduli of adjacent portions.

8. The display device of claim 1, wherein each of the plurality of adhesive layers comprises a Young's modulus that is less than or equal to 0.5 MPa.

9. The display device of claim 1, wherein the plurality of functional layers of the OLED display module comprise Young's moduli that are less than or equal to 10 GPa.

10. (canceled)

11. The display apparatus of claim 1, wherein each of the plurality of adhesive layers comprises one or more of a silicone-based polymer, an acrylate-based polymer, an epoxy-based polymer, a thiol-containing polymer, a polyimide-based material, or a polyurethane.

12. (canceled)

13. The display device of claim 1, wherein the glass substrate comprises a Young's modulus of greater than or equal to 60 GPa and less than or equal to 80 GPa, wherein a first functional layer of the plurality of functional layers is disposed adjacent to the attachment adhesive layer and comprises a Young's modulus of less than or equal to 6 GPa and a thickness of less than or equal to 1 mm, wherein the attachment adhesive layer comprises a thickness of greater than or equal to 0.5 mm and a Young's modulus of less than or equal to 0.4 MPa.

14. (canceled)

15. (canceled)

16. (canceled)

17. The display device of claim 1, wherein each one of the plurality of neutral planes is contained in one of the plurality of functional layers, one of the plurality of adhesive layers, or the glass substrate such that each of the plurality of functional layers, the plurality of adhesive layers, and the glass substrate contains one of the m neutral planes.

18. The display device of claim 17, wherein each one of the plurality of neutral planes is disposed in a central 20% of a thickness of one of the plurality of functional layers, one of the plurality of adhesive layers, or the glass substrate.

19. A vehicle interior system comprising:
a glass substrate comprising a first major surface and a second major surface opposite the first major surface, wherein the glass substrate comprises a length extending in a first direction that is greater than or equal to 200 mm and a width extending in a second direction perpendicular to the first direction that is greater than or equal to 100 mm;
a support structure mechanically coupled to the glass substrate and retaining the glass substrate in a curved configuration such that at least a portion of the glass substrate is curved along at least one of the first direction and the second direction;
an organic light emitting diode (OLED) display module attached to the second major surface via an attachment adhesive layer disposed directly on the second major surface, wherein:
the OLED display module is retained in the curved configuration via the attachment adhesive layer such that different portions of the OLED display module are placed in tension and compression,
the OLED display module comprises a plurality of functional layers attached to one another via a plurality of layers of display adhesive disposed between successive ones of the plurality of functional layers, and
the plurality of layers of display adhesive each comprise a Young's modulus and thickness selected such that the compression and tension placed on the different portions of the OLED display module results in each of the plurality of functional layers and each of the plurality of layers of display adhesive containing a separate neutral plane.

20. The vehicle interior system of claim 19, wherein the OLED display module covers at least 50% of a surface area of the second major surface.

21. The vehicle interior system of claim 19, wherein the support structure retains the glass substrate and the OLED display module such that entireties of the glass substrate and the OLED display modules are curved in the first direction.

22. (canceled)

23. The vehicle interior system of claim 19, wherein the layer of attachment adhesive and the plurality of layers of display adhesive each comprise a Young's modulus that is less than or equal to one hundredth of the young moduli of adjacent portions.

24. The vehicle interior system of claim 19, wherein the layer of attachment adhesive and the plurality of layers of display adhesive each comprise a Young's modulus that is less than or equal to 1.5 MPa.

25. The vehicle interior system of claim 19, wherein the plurality of functional layers of the OLED display module comprise Young's moduli that are less than or equal to 10 GPa.

26. The vehicle interior system of claim 19, wherein the attachment adhesive layer and the plurality of layers of display adhesive each comprise an optically clear adhesive and/or a pressure sensitive adhesive.

27. The vehicle interior system of claim 19, wherein the first major surface and the second major surface define a thickness of the glass substrate that is greater than or equal to 0.3 mm and less than or equal to 2 mm, wherein the glass substrate comprises a chemically strengthened glass with a Young's modulus of greater than or equal to 60 GPa and less than or equal to 80 GPa, wherein a first functional layer of the plurality of functional layers is disposed adjacent to the attachment adhesive layer and comprises a Young's modulus of less than or equal to 6 GPa and a thickness of less than or equal to 1 mm, wherein the attachment adhesive layer comprises a thickness of greater than or equal to 0.5 mm and a Young's modulus of greater than or equal to 0.04 MPa and less than or equal to 0.4 MPa.

28.-41. (canceled)
